(19) United States
(12) Patent Application Publication
(10) Pub. No.: US 2026/0190866 A1
(43) Pub. Date: Jul. 2, 2026

(54) ELECTRON SPIN WAVE MULTIPLEXING DEVICE

(71) Applicant: TOHOKU UNIVERSITY, Sendai-shi, Miyagi (JP)

(72) Inventors: Makoto KODA, Sendai-shi (JP); Takeshi SEKI, Sendai-shi (JP); Tetsuya UEMURA, Sapporo-shi (JP); Yasushi YUMINAKA, Maebashi-shi (JP)

(21) Appl. No.: 18/857,246

(22) PCT Filed: Apr. 20, 2022
(86) PCT No.: PCT/JP2022/018255

§ 371 Date: Oct. 16, 2024

(51) Int. Cl. H10N 50/20; H04B 10/60; H04B 10/90; H10N 50/85; H10N 59/00

(52) U.S. Cl. CPC H10N 50/20; H04B 10/60; H04B 10/90; H10N 50/85; H10N 59/00

(57) ABSTRACT

The present invention includes a receiving unit that includes a first solid-state device having a semiconductor quantum well structure, and receives multiple electron spin waves, a modulation unit that includes a second solid-state device having a semiconductor quantum well structure and connected to the receiving unit, and generates a multiplexed electron spin wave by synthesizing the electron spin waves from the receiving unit, and a separation unit that includes a third solid-state device having a semiconductor quantum well structure and connected to the modulation unit, receives the multiplexed electron spin wave synthesized in the modulation unit, and separates the multiple electron spin waves from the multiplexed electron spin wave. The modulation unit is a modulation unit that has a function of superposing the multiple electron spin waves by controlling an amplitude, a phase, and a polarization degree of freedom of the electron spin waves utilizing a persistent spin helix state in crystal orientation dependence of an effective magnetic field due to a spin-orbit interaction generated in a semiconductor quantum well structure.

### TECHNICAL FIELD

The present invention relates to an electron spin wave multiplexing device.

### BACKGROUND ART

In modern society, opportunities for handling a large amount of information, such as the fifth generation mobile communication system (5G), artificial intelligence (AI), and the Internet of Things (IoT), are increasing more and more. Currently, the main means of transmitting this information is “light”, and use of optical fiber enables long-distance and large-capacity transport. Characteristics of light as a wave include “parallelism” (waves do not interfere with each other) and “multiplexing properties” (waves can be superposed). Thus, wavelength division multiplexing (WDM), which applies these characteristics, has made it possible to transmit multiple pieces of information simultaneously over a single optical fiber.

On the other hand, in electronic devices such as semiconductor integrated circuits, it is essentially impossible to transmit multiple pieces of information simultaneously. This is because properties of electrons are greatly different from those of light, and parallelism and multiplexing properties cannot be incorporated. However, when electronic devices that have the characteristics of light are achieved, it may be possible to achieve various information processing platforms on a single information carrier, allowing coexistence of analog and digital signals and mixture of von Neumann and non-von Neumann type calculations.

Accordingly, what the inventors believe is that “electron spin waves” can be used as this ultimate information carrier.

The electron spin waves can be generated by an effective magnetic field created by spin-orbit interactions existing inside a semiconductor. For example, two types of spin-orbit interactions exist in III-V semiconductor quantum well structures. These are the effective magnetic fields created by the Rashba spin-orbit interaction (clockwise arrows illustrated in FIG. 6(a)) and the Dresselhaus spin-orbit interaction (arrows illustrated in FIG. 6(b)).

When these two effective magnetic fields have the same value, a direction of the effective magnetic field is oriented in one axial direction (arrows illustrated in FIG. 6(c)), and the effective magnetic field direction is fixed to one, and spin relaxation is suppressed.

This state can be called a persistent spin helix state. The electron spin rotates around the effective magnetic field, generating a wave of the electron spin as illustrated in FIG. 7. In FIG. 7, the relationship λ₊=+(1/q₀) holds. In FIG. 7, q₀ means a wave number specific to the material.

By satisfying this condition, the electron spin waves can exist stably in the semiconductor, and an information carrier using the electron spin waves can be created.

“Electron spin waves” is a phenomenon in which the spin, which is a magnetic property of an electron, propagates through space while changing direction, and has properties of a classical “wave”. As illustrated in FIG. 7, a length of one rotation during which the spin direction goes from upward to downward and then back to upward again can be defined as the wavelength λ of the electron spin wave.

This wavelength can be used as information, and by treating different wavelengths as different pieces of information, the pieces of information can be multiplexed using electron spin waves. Therefore, information in the form of light waves can be transferred direct into a solid.

Since electron spin waves can exist stably in a state in which spin relaxation is suppressed, it is considered that the electron spin waves can propagate long distances and the wavelength thereof can be freely controlled depending on the strength of the effective magnetic field.

Furthermore, by controlling an amplitude, a phase, and a polarization degree of freedom, it may be possible to superpose electron spin waves. That is, since electron spin waves have the same characteristics as light, it is considered that multiplexing of information, which has been conventionally performed using optical fibers, can be achieved even by solid-state electronic devices.

The inventors have previously studied the above-described electron spin waves, and have published part of the study contents related to the electron spin waves in the following non-patent document 1.

### CITATION LIST

### Non-Patent Document

Non-Patent Document 1: Y. Kunihashi, M. Kohda, J. Nitta, et al, “Drift transport of helical spin coherence with tailored spin-orbit interactions”, NATURE COMMUNICATIONS, Published 8 Mar. 2016.

### SUMMARY OF INVENTION

### Technical Problem

A problem with the above-described WDM system is that as the number of pieces of information to be transmitted simultaneously increases, the same number of photoelectric converters need to be prepared, raising concerns about an increase in volume and an increase in power consumption. On the other hand, a transmission system using electron spin waves is considered to make it possible to generate multiplexed spin wave signals by directly transferring the multiplexed optical signals to a semiconductor, thereby enabling seamless parallel information processing.

This will help suppress an increase in the number of devices, and is expected to lead to an increase in the speed through parallelism and multiplexing properties of waves.

In today's information system infrastructure, information carriers of light, electric charge, and spin are highly efficiently controlled and ultimately utilized for communication, computation, and recording to support an information society. Specifically, in information processing, a larger amount of information is processed than in sequential information processing based on binary logic circuits using 0s and 1s, and information recording is recorded by magnetization of the information 0s and 1s=upward and downward spins.

Only optical communication uses wave nature of light to multiplex information. In this situation, qualitative differences between the information carriers create bottlenecks in mutual conversion of information. For example, the wave nature of light and the particle nature (electric charge) of electrons cannot be interchanged. Thus, with an explosive increase in communication capacity expected in the future, information transmission is possible by multiplexing the information, but information processing requires sequential computation of all of the multiplexed information, which requires a huge number of information devices, resulting in serious increases in power consumption.

In order to solve the problems created by the qualitative differences in information carriers, specifically the difference between the wave nature of light and the particle nature of electrons, a new information carrier is required to move away from sequential computational processing and allow high-level sharing of information across the entire system. To achieve this, it is considered that it is possible to achieve high information density by utilizing information carriers that have wave nature, which can be referred to as wave nature information carriers herein, and taking advantage of parallelism and multiplexing properties of waves. Furthermore, by using wave nature information carriers for all communication, processing, and recording, it is considered that it is possible to seamlessly achieve mutual conversion of multiplexed information and build a new information system infrastructure that can handle an enormous amount of information.

The present invention has been made based on the background described above, and an object of the present invention is to provide an electron spin wave multiplexing device that uses electron spin waves and can handle continuous changes in spin direction accompanying spin rotation as analog signals, thereby enabling simultaneously processing of digital information and analog information.

### Solution to Problem

(1) An electron spin wave multiplexing device according to the present invention includes a receiving unit that includes a first solid-state device having a semiconductor quantum well structure, and receives a multiplexed electron spin wave by synthesizing multiple electron spin waves, a modulation unit that includes a second solid-state device having a semiconductor quantum well structure and connected to the receiving unit, and modulates the multiplexed electron spin wave from the receiving unit, and a recording unit that includes a third solid-state device having a semiconductor quantum well structure and connected to the modulation unit, receives the multiplexed electron spin wave passed through the modulation unit and includes multiple recording magnetic materials that record information contained in the multiplexed electron spin wave in a nonvolatile manner, in which the modulation unit is a modulation unit that has a function of controlling at least one of an amplitude, a phase, and a polarization degree of freedom of the multiple electron spin waves by utilizing a persistent spin helix state in crystal orientation dependence of an effective magnetic field due to a spin-orbit interaction generated in a semiconductor quantum well structure.
(2) In the electron spin wave multiplexing separation detection device according to (1) of the present invention, it is preferable that the electron spin wave multiplexing device, by transmitting an electron spin wave having a wavelength equal to a specific wavelength determined uniquely from spin-orbit interaction strength and eliminating an electron spin wave having a wavelength different from the specific wavelength determined uniquely from the spin-orbit interaction strength in the solid-state device having the semiconductor quantum well structure, has a function of transmitting only an electron spin wave having a specific wavelength in the solid-state device.
(3) In the electron spin wave multiplexing device according to (1) or (2) of the present invention, it is preferable that when the number of the multiple electron spin waves is large, the electron spin wave multiplexing device has a function of converting data obtained by real space measurement into data in wave number space by fast Fourier transform and analyzing the data.
(4) In the electron spin wave multiplexing device according to any one of (1) to (3) of the present invention, it is preferable that the modulation unit is provided with one or more of a gate electrode for voltage application, a ferromagnetic layer for spin injection and amplification, and a wiring coupling unit that couples the multiple electron spin waves.
(5) In the electron spin wave multiplexing device according to any one of (1) to (4) of the present invention, it is preferable that the multiple recording magnetic materials each having a base magnetic layer and a recording magnetic layer are arrayed in the recording unit, the base magnetic layer is a magnetization reversal layer that excites a magnon using each of the multiple electron spin waves and is capable of magnetization reversal by resonating with excitation of the magnon, the recording magnetic layer has a function of magnetization reversal corresponding to the magnetization reversal of the base magnetic layer and nonvolatile recording of the information contained in the multiplexed electron spin wave with this magnetization reversal, and the information contained in the multiplexed electron spin wave is recorded as multi-states by the multiple recording magnetic materials arrayed.
(6) In the electron spin wave multiplexing device according to any one of (1) to (5) of the present invention, it is preferable that a set difference gate is configured by providing a gate electrode for voltage application to the modulation unit.
(7) In the electron spin wave multiplexing device according to any one of (1) to (6) of the present invention, it is preferable that a set generation gate is configured by providing a ferromagnetic layer for spin injection and amplification to the modulation unit.
(8) In the electron spin wave multiplexing device according to any one of (1) to (7) of the present invention, it is preferable that a set sum gate is configured by providing a wiring coupling unit that couples the multiple electron spin waves to the modulation unit.
(9) In the electron spin wave multiplexing device according to any one of (1) to (8) of the present invention, it is preferable that the receiving unit has a function of generating the multiplexed electron spin wave by irradiation with a laser on which information contained in a multiplexed polarization beam for optical communication is recorded, and has a multiplexed information transmission function by writing information corresponding to the multiplexed polarization beam for optical communication in the multiplexed electron spin wave.
(10) In the electron spin wave multiplexing device according to any one of (1) to (5) of the present invention, it is preferable that a parallel computer is constructed by including the set difference gate according to (6), the set generation gate according to (7), and the set sum gate according to (8).
(11) In the electron spin wave multiplexing device according to any one of (5) to (10) of the present invention, it is preferable that the multiple recording magnetic materials are provided vertically and horizontally in a plane direction of the recording unit, and each of the multiple recording magnetic materials has a function as resonant switching by spin pumping due to a spin transfer effect from the multiplexed electron spin wave.
(12) In the electron spin wave multiplexing device according to (11) of the present invention, it is preferable that the electron spin wave multiplexing device employs a structure that exhibits angle dependence due to a planar Hall effect for each of the multiple recording magnetic materials, and has a function of reading information in the recording unit by reading in-plane magnetization in a region where the multiple recording magnetic materials are formed when each of the multiple recording magnetic materials is magnetically oriented in a film surface.
(13) In the electron spin wave multiplexing device according to (11) of the present invention, it is preferable that the electron spin wave multiplexing device employs a structure that exhibits an anomalous Hall effect in each of the multiple recording magnetic materials, and has a function of reading information in the recording unit by reading a perpendicular magnetization component in a region where the multiple recording magnetic materials are formed when each of the multiple recording magnetic materials is magnetically oriented perpendicular to a film surface.

### Advantageous Effects of Invention

According to the present invention, it is possible to provide an electron spin wave multiplexing device capable of multiplexing electron spin waves by controlling an amplitude, a phase, and a polarization degree of freedom of the electron spin waves.

Individual multiplexed electron spin waves multiplexed contain continuous analog signal information such as the amplitude and the phase in addition to digital signal information of 0 and 1 due to up spin and down spin, thus enabling simultaneous processing of digital and analog information. Thus, it is possible to provide a transmission device and a signal processing device for electron spin waves that exhibit an effect of enabling switching between von Neumann and non-von Neumann type calculations.

### BRIEF DESCRIPTION OF DRAWINGS

FIG. 1 shows spin waves generated by a Monte Carlo simulation, in which FIG. 1(a) is a diagram showing a first example of spin distribution of up spin and down spin in real space, FIG. 1(b) is a diagram showing a state where Fourier transform is applied to a state shown in FIG. 1(a), FIG. 1(c) is a diagram showing a second example of spin distribution of up spin and down spin in real space, FIG. 1(d) is a diagram showing a state where Fourier transform is applied to a state shown in FIG. 1(c), FIG. 1(e) is a diagram showing a third example of spin distribution of up spin and down spin in real space, and FIG. 1(f) is a diagram showing a state where Fourier transform is applied to a state shown in FIG. 1(e).

FIG. 2 is a diagram in which spin waves having a wavelength equal to a specific wavelength (λ₀=9.0 μm) that is uniquely determined by strength of a spin-orbit interaction in a solid is excited at time 0, and is a diagram showing a case of stable long-wavelength spin waves.

FIG. 3 is a diagram in which spin waves having a wavelength (λ₀=4.5 μm) different from the specific wavelength (λ₀=9.0 μm) that is uniquely determined by strength of a spin-orbit interaction in a solid is excited at time 0, and is a diagram showing a case of unstable short-wavelength spin waves.

FIG. 4 is a diagram showing time evolutions of spin distributions when spin waves of different wavelengths are incident on the same solid.

FIG. 5 shows drift transport of a multiplexed spin wave and an electron spin wave filter, in which FIG. 5(a) is a diagram showing a cross section at Y=0 of real space distribution of a multiplexed spin wave shown in FIG. 5(b), FIG. 5(b) is a diagram showing real space distribution of the multiplexed spin wave having three wavelength components of λ₁=20 μm, λ₂=6.7 μm, and λ₃=3.3 μm, FIG. 5(c) is a diagram showing reciprocal space distribution of the multiplexed spin wave having the same three wavelength components, FIG. 5(d) is a diagram showing a state in which the multiplexed wave shown in FIG. 5(b) is incident on a region where λ₂ is stably present and drift transported in the +Y direction for 1 ns, FIG. 5(e) is a diagram showing a state in which the multiplexed wave shown in FIG. 5(c) is incident on a region where λ₂ is stably present and drift transported in the +Y direction for 1 ns, FIG. 5(f) is a diagram showing a state in which the multiplexed wave shown in FIG. 5(b) is incident on a region in which λ₃ is stably present and drift transported in the +Y direction for 1 ns, FIG. 5(g) is a diagram showing a state in which the multiplexed wave shown in FIG. 5(c) is incident on a region in which λ₃ is stably present and drift transported in the +Y direction for 1 ns.

FIG. 6 is a diagram for describing two types of spin-orbit interactions that exist in a III-V semiconductor quantum well structure, in which FIG. 6(a) is a diagram showing the Rashba spin-orbit interaction, FIG. 6(b) is a diagram showing the Dresselhaus spin-orbit interaction, and FIG. 6(c) is a diagram showing a persistent spin helix state.

FIG. 7 is an explanatory diagram showing a concept of an electron spin wave.

FIG. 8 is an explanatory diagram showing an example of a circuit configuration that has an example of a III-V semiconductor quantum well structure and is capable of multiplexing electron spin waves.

FIG. 9 is a graph showing that a large effective magnetic field exceeding 10 T can be generated by controlling a gate voltage in the circuit configuration shown in FIG. 8.

FIG. 10 is an explanatory diagram showing an overview of superposition, transport, and separation detection of a multiplexed electron spin wave.

FIG. 11 is an explanatory diagram showing a concept of providing a region where a gate can be applied midway in transport of a multiplexed electron spin wave.

FIG. 12 is a schematic diagram showing a specific structure of a part that performs gate control and an equivalent circuit of a set difference gate corresponding to this structure.

FIG. 13 is a schematic diagram showing a specific structure of a part that performs spin injection and amplification and an equivalent circuit configuration of a set generation gate corresponding to this structure.

FIG. 14 is a schematic diagram showing a specific structure used when performing superposition to obtain a multiplexed electron spin wave by wiring coupling and an equivalent circuit of a set sum gate corresponding to this structure.

FIG. 15 is an explanatory diagram for showing a concept of generating a multiplexed electron spin wave using a multiplexed polarization beam.

FIG. 16 is a perspective view showing an example of a structure for collectively photoelectrically converting multiplexed information.

FIG. 17 shows a configuration for generating and amplifying an electron spin wave by utilizing a magnon resonance excitation phenomenon by inputting a multiplexed electron spin wave, in which FIG. 17(a) is a schematic configuration diagram of a device for injecting spins by spin pumping, FIG. 17(b) is a schematic diagram showing a configuration of elements for magnetization reversal by magnon resonant excitation, and FIG. 17(c) is a schematic diagram for describing a magnon.

FIG. 18 is a schematic diagram showing a configuration for selecting, writing, and further reading information contained in a multiplexed electron spin wave.

FIG. 19 is a schematic diagram showing write conditions for electrically selectively writing information by electron spin waves in the configuration shown in FIG. 18.

FIG. 20 is an explanatory diagram for describing a method for multi-state recording of information received from electron spin waves.

FIG. 21 is a schematic diagram showing an electron spin wave multiplexing device according to an embodiment of the present invention.

FIG. 22 is an explanatory diagram showing a basic structure for confirming that spin injection, transport, and detection are possible in a layered structure of ferromagnetic metals and a semiconductor.

FIG. 23 is an explanatory diagram showing a basic structure for confirming that an electron spin wave can be controlled by spin pumping in the layered structure of the ferromagnetic metals and the semiconductor.

FIG. 24 is an explanatory diagram showing a basic structure for confirming that dynamic behavior of a ferromagnetic metal can be modulated by an electron spin wave in the layered structure of the ferromagnetic metals and the semiconductor.

FIG. 25 is an explanatory diagram showing a basic structure for confirming that multi-state recording for a ferromagnetic metal memory by an electron spin wave is possible in the layered structure of the ferromagnetic metals and the semiconductor.

FIG. 26 is a schematic diagram showing a specific configuration for branching a multiplexed electron spin wave, obtaining set differences and a set sum, and recording information in the electron spin wave multiplexing device according to the same embodiment, in which (a) is a schematic diagram of a branching section, (b) is a schematic diagram showing a configuration for obtaining the set differences, (c) is a schematic diagram showing a configuration for obtaining the set sum, and (d) is a schematic diagram of a configuration for recording information.

FIG. 27 is an equivalent circuit diagram corresponding to a structure for obtaining the set differences and the set sum in the device shown in FIG. 26.

FIG. 28 is a diagram showing conditions of an external magnetic field and an excitation frequency for selective writing in a recording unit including a recording magnetic material.

FIG. 29 is a circuit diagram showing an example of an optical communication device including a digital signal processing circuit, a DA converter, an AD converter, a polarization multiplexed optical modulator, and a coherent receiver.

FIG. 30 is a configuration diagram showing an electron spin wave multiplexing device that can replace part of the circuit shown in FIG. 29.

### DESCRIPTION OF EMBODIMENT

Hereinafter, an example of an embodiment of the present invention will be described in detail based on the accompanying drawings. Note that in the drawings used in the following description, to make features easy to understand, portions corresponding to the features are sometimes indicated enlarged for the sake of convenience.

First, a technique of superposing electron spin waves will be described.

A wavelength of the electron spin wave changes depending on strength of an effective magnetic field derived from a spin-orbit interaction generated in a semiconductor quantum well structure. Since specific wavelengths correspond one-to-one to pieces of information to be transmitted, the inventors believe that the pieces of information are able to be distinguished by examining the wavelengths of the spin waves.

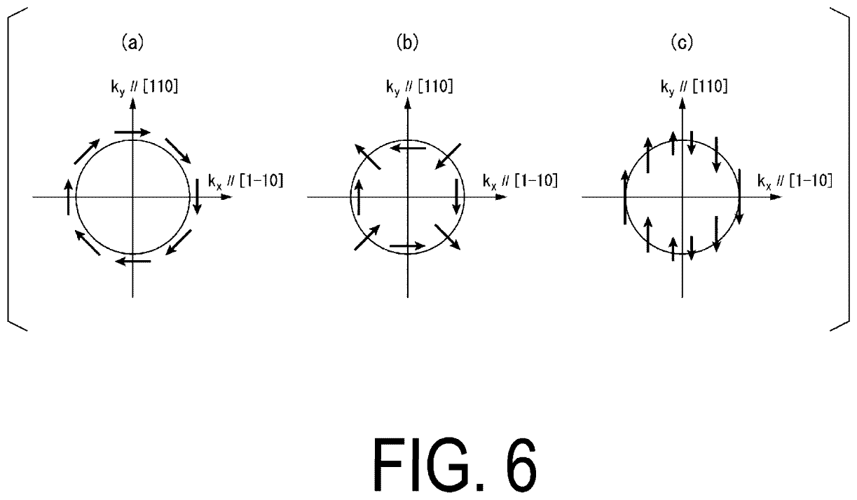

The inventors have found that the strength of the effective magnetic field can be changed by controlling a gate voltage using a gate structure formed on a surface of a semiconductor, and spin waves of any wavelength can be generated. Furthermore, in two-dimensional electron gas in a semiconductor quantum structure, the wavelength of the spin waves changes depending on an in-plane crystal orientation. In a persistent spin helix state, as shown in FIG. 6(c), an effective magnetic field received by electrons moving in a specific crystal orientation direction can be made 0. Therefore, by restricting a direction of electron motion using a wire structure or the like, the wavelength of a stable spin wave can be changed from a specific value to infinity (plane wave). This makes it possible to control an amplitude, a phase, and a degree of freedom of polarization of the electron spin wave.

A typical material capable of generating electron spin waves has a III-V compound semiconductor quantum well structure, and a solid-state device having a layered structure as shown in Table 1 below can be employed.

However, materials capable of generating similar electron spin waves can be achieved in various solid-state devices, such as a II-VI semiconductor quantum well structure, a SrTiO₃/LaAlO₃ quantum well structure, and a SiGe quantum well structure in addition to the III-V semiconductor.

Note that various crystal orientations can be achieved with respect to the crystal orientation, and more specifically, crystal orientations described in D. Iizasa et al., Physical Review B, 101, (2020), 245417, for example, a layered structure shown in Table 1 shown below can be employed. In Table 1, constituent materials and layer thicknesses (nm) of the respective layers are shown, and QW stands for quantum well structure.

TABLE 1

| | | | |
|---|---|---|---|
| ud-GaAs | 5 | nm | |
| n-Al_{0.3}Ga_{0.7}As | 20 | nm | Si doped |
| ud-Al_{0.3}Ga_{0.7}As | 10 | nm | |
| ud-GaAs | 20 | nm | QW |
| ud-Al_{0.3}Ga_{0.7}As | 100 | nm | |
| ud-GaAs | 2 | nm | |
| ud-Al_{0.3}Ga_{0.7}As | 18 | nm | |
| ud-GaAs | 200 | nm | |

| | |
|---|---|
| GaAs (001) | Substrate |

(ud stands for undoped.)

Note that as a solid-state device having a III-V compound semiconductor quantum well structure capable of generating electron spin waves, a layered structure shown in Table 2 below may be employed. Table 2 shows constituent materials and layer thicknesses (nm) of the respective layers.

TABLE 2

| | | | |
|---|---|---|---|
| n⁺-GaAs | 10 | nm | Si doped |
| n-GaAs | 20 | nm | Si doped QW |
| ud-GaAs | 60 | nm | |
| ud-AlₓGa₁₋ₓAs | 15 | nm | |
| n-AlₓGa₁₋ₓAs | 10 | nm | Si doped |
| ud-AlₓGa₁₋ₓAs | 100 | nm | |
| ud-GaAs | 100 | nm | |

| | |
|---|---|
| GaAs (001) | Substrate |

(n⁺ means higher doping concentration than n.)

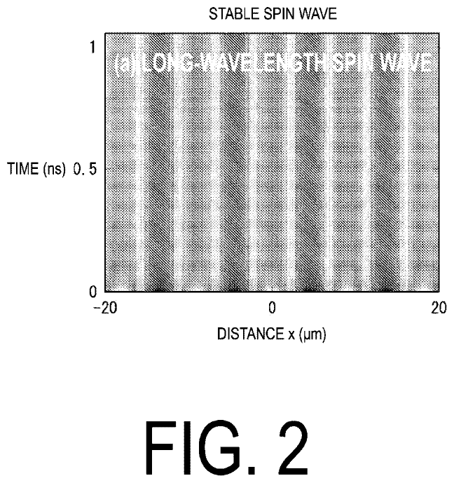

As shown in FIG. 2(a) on page 3 of the document, Yoji Kunihashi et al. “Drift-Induced Enhancement of Cubic Dresselhaus Spin-Orbit Interaction in a Two-Dimensional Electron Gas” Physical Review Letter 119, 187703 (2017), it is described that a wavelength of an electron spin wave changes depending on the drift velocity of an electron, that is, the energy of the electron.

Based on this finding, it is possible to generate different spin wave wavelengths by exciting electron spins having different electron energies with light. Therefore, specifically, a multiplexed spin wave can be formed by superposing and exciting circular polarizations of different wavelengths.

In a method other than the method described above, a ferromagnet/semiconductor junction can be used to implement electric spin injection from a ferromagnetic material to a semiconductor, thereby generating spin-polarized electrons in the semiconductor.

In the above-described structure, a polarization rate and an electron density of the electron spin can be changed depending on an applied bias voltage. Therefore, in principle, spatial distribution of the electron spin polarization and the electron density created by multiplexed electron spin waves can be generated in a semiconductor by changing the bias voltage of the electric spin injection.

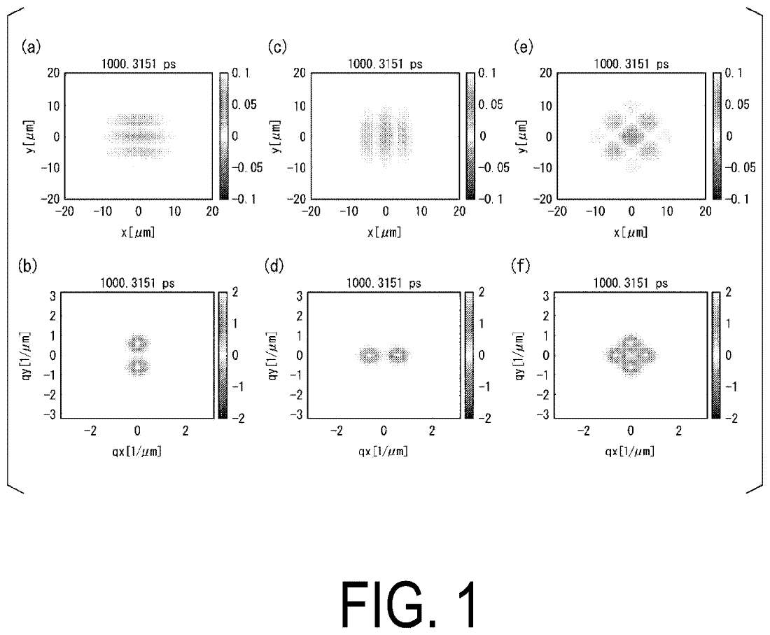

In this application, a circuit configuration similar to the circuit shown in FIG. 1 in the above-mentioned document can be applied.

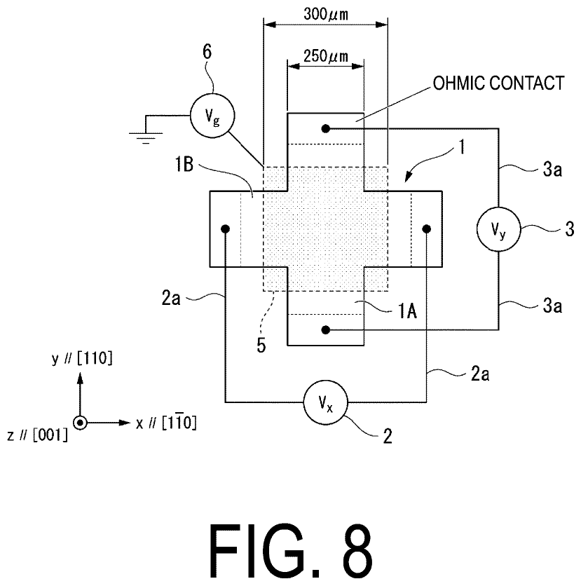

FIG. 8 is a schematic diagram showing a circuit similar to the circuit shown in FIG. 1 in the same document.

In this circuit, a vertical strip-shaped wiring 1A, a horizontal strip-shaped wiring 1B, and an integrated wiring coupling unit 1 that couples the vertical strip-shaped wiring 1A and the horizontal strip-shaped wiring 1B in a cross shape form a layered structure shown in Table 1 above, and by fabricating a Hall bar structure, an electric field can be applied in the x direction or the y direction in FIG. 8.

In the circuit in FIG. 8, widths of the wirings 1A and 1B are each formed to 250 μm. Both ends of the wirings 1A and 1B are connected to wirings 2a and wirings 3a, which are connected to a power source 2 and a power source 3, respectively. These connection parts are configured as ohmic contact parts so that voltages indicated by a voltage Vₓ in the x direction and a voltage V_{y} in the y direction shown in FIG. 8 can be applied.

Further, a gate voltage (V_{g}) can be applied from a power source 6 by depositing a gate electrode 5, which is a Cr/Au thin film, in a region indicated by a rectangular frame line (a region surrounded by a rectangular frame 300 μm wide in length and width) including an intersection of the wiring coupling unit 1. In addition, sizes of respective parts of the circuit can be made equivalent to those of the circuit diagram in FIG. 1 in the same document.

In the structure in FIG. 8, the film thickness of the quantum well structure is made thinner as shown in Table 1, which can be considered as a structure in which the electron motion is restricted from three dimensions to two dimensions, and the duration of the electron spin waves that appear here can be grasped. The strength of the high-order Dresselhaus magnetic field depends on a crystal orientation when confined in two dimensions.

From this circuit, it is possible to draw a Monte Carlo simulation.

The Monte Carlo simulation was performed using the latest version (R2020b) of “Matlab”, which is calculation software manufactured by MathWorks. The time evolution of an electron spin when the electron spin senses an effective magnetic field and undergoes precession can be described by the Bloch equations. Thus, after generating spin polarization at t=0, the position information and the spin components of the electron spin were updated using an equation consisting of parameters shown in Table 3 described later, and an analysis was performed as follows.

For example, in the circuit shown in FIG. 8, the gate voltage (V_{g}) can be applied to a region enclosed by a broken line as a gate structure. By applying the gate voltage (V_{g}) to this gate structure, electron spin waves corresponding to the spin-orbit interaction generated by V_{g} can be formed in the region enclosed by the rectangular frame. Different electron spin waves can be generated by changing the value of V_{g}, so any wavelength can be generated by controlling the value of V_{g}.

In FIG. 8, the x direction indicates a direction parallel to [110] in the crystal of the quantum well structure, the y direction indicates a direction parallel to [110] in the crystal of the quantum well structure, and the z direction indicates a direction parallel to [001] in the crystal of the quantum well structure.

It should be noted that an overline attached to the Miller indices described in [ ] indicating the above-described crystal direction is replaced with an underline because the overline cannot be written in the patent specification.

As described above, the technique capable of generating different electron spin waves by changing the value of the gate voltage (V_{g}) is described in a document previously published by the inventors: Makoto Kohda, et al. “Enhancement of spin-orbit interaction and the effect of interface diffusion in quaternary InGaAsP/InGaAs heterostructures” Physical Review B 81, 115118 (2010).

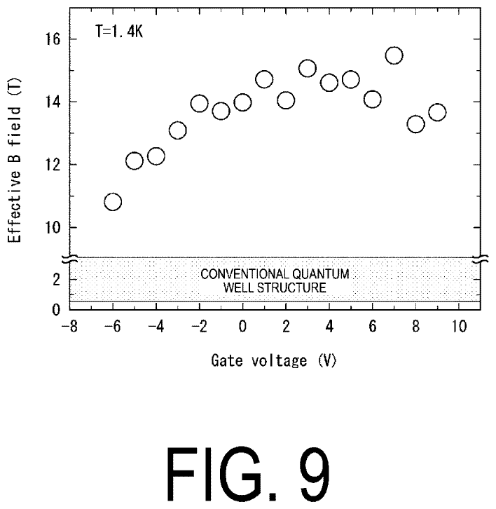

For example, FIG. 9 shows a relationship between the gate voltage and the effective magnetic field described in the above-mentioned document, and shows that by precisely controlling the gate voltage, an effective magnetic field exceeding 10 T (tesla) can be applied.

The results shown in FIG. 9 were results obtained for a solid-state device having an In_{0.52}Al_{0.48}As layer (thickness 200 nm), an InGaAsP layer (thickness 5 nm), an In_{0.8}Ga_{0.2}As layer (thickness 10 nm), an InGaAlAs layer (thickness 3 nm), and an In_{0.52}Al_{0.48}As layer (thickness 25 nm) layered on an InP substrate.

FIG. 1 shows a state in which electron spin waves generated in different directions are superposed. A Monte Carlo simulation was used to generate the electron spin waves, and specific parameters thereof are shown in Table 3, which will be described later.

Upper diagrams in FIG. 1 are reciprocal spaces (wave number spaces) obtained by performing two-dimensional Fourier transform on lower diagrams in FIG. 1, and show wave numbers, which are reciprocals of wavelengths.

FIG. 1(a) is a diagram showing a first example of spin distribution of up spins and down spins in real space, and FIG. 1(b) is a diagram showing reciprocal space (wave number space) obtained by performing two-dimensional Fourier transform on the state shown in FIG. 1(a).

In FIG. 1(a), three rows of spin distributions in the vertical direction and distributed in the horizontal direction are shown. Among the three rows in the vertical direction, the central distribution indicates a region having a high proportion of up spins, while the two top and bottom distributions indicate regions having a high proportion of down spins.

FIG. 1(c) is a diagram showing a second example of spin distribution of up spins and down spins in real space, and FIG. 1(d) is a diagram showing reciprocal space (wave number space) obtained by performing two-dimensional Fourier transform on the state shown in FIG. 1(c).

In FIG. 1(c), three rows of spin distributions in the horizontal direction and distributed in the vertical direction are shown. Among the three rows in the horizontal direction, the central distribution indicates a region having a high proportion of up spins, and the two left and right distributions indicate regions having a high proportion of down spins.

As can be seen in FIGS. 1(a) and (c), the direction of the electron spin waves changes in accordance with the direction of the spin-orbit interaction.

The two-dimensional Fourier transform is a program capable of transforming a two-dimensional matrix using a fast Fourier transform algorithm. In principle, this is equivalent to performing the fast Fourier transform twice in the x direction and in the y direction.

FIG. 1(e) is a diagram showing a third example of spin distribution of up spins and down spins in real space, and FIG. 1(f) is a diagram showing reciprocal space (wave number space) obtained by performing two-dimensional Fourier transform on the state shown in FIG. 1(e).

In FIG. 1(e), regions having a high proportion of down spins are distributed in four upper and lower directions of the left and right of a region having a high proportion of up spins distributed in the center, and regions having a high proportion of up spins are present in two upper and lower directions.

When the wavelength of the electron spin wave is λ, peaks appear at positions of a wave number q having a magnitude of q=2π/λ. FIG. 1(e) is obtained by superposing the waveforms of FIGS. 1(a) and 1(c), and FIG. 1(f) obtained by Fourier-transforming FIG. 1(e) maintains the peak positions of FIGS. 1(b) and 1(d). This means that the electron spin waves have parallelism and multiplexing properties like ordinary waves.

The results shown in FIG. 1 indicate that when two types of electron spin waves are superposed, the electron spin waves are superposed while maintaining specific wavelengths (wave numbers) thereof. This proves that electron spin waves have parallelism and multiplexing properties like light and can be superposed without interfering with each other.

As shown in FIGS. 1(b), (d), and (e), when the spin distribution is grasped in the reciprocal space (wave number space) obtained by performing the two-dimensional Fourier transform, the spin distribution can be grasped more clearly than when the spin distribution is grasped in the real space. Therefore, it was found that when two types of electron spin waves were superposed, the electron spin waves were able to be superposed while maintaining specific wavelengths (wave numbers) thereof, and when multiple electron spins were superposed and transmitted, the multiple electron spins were able to be transported without interfering with each other, and it was also found that waves were able to be superposed as electron spin waves. Therefore, wavelength division multiplexing can be applied to electron spin waves as well as to light.

TABLE 3

| | FIG. | FIG. | FIG. | FIG. | FIG. | FIG. |
|---|---|---|---|---|---|---|
| | 1(a) | 1(c) | 2 | 3 | 5(a) | 5(f) |
| α[meV · Å] | −1.8 | +1.8 | −2.0 | | 2.7 | −5.4 |
| β₁[meV · Å] | 2.0 | | 2.2 | | −2.7 | 5.4 |
| β₃[meV · Å] | 0.2 | | 0.2 | | 0 | |
| Ds[m²/s] | 0.011 | | | | | |
| Ns[1/m²] | 1.7 × 10¹⁵ | | | | | |
| g | −0.26 | | | | | |
| Electrons | 50000 | | 30000 | | 500000 | |
| μ[m²/(V · s)] | 11 | | | | | |
| Eex[V/m] | 0 | | | | 0.1 | |

In Table 3, α: strength of Rashba spin-orbit interaction, β₁: strength of Dresselhaus spin-orbit interaction (linear term), β₃: strength of Dresselhaus spin-orbit interaction (cubic term), Ds: spin diffusion constant, Ns: carrier density, g: g factor, Electrons: number of electrons, μ: electron mobility, and Eex: external electric field, and in all cases, no external magnetic field is applied. Note that the simulation assumes that electrons are scattered in random directions every 10 ps.

### Multiplexed Information Transmission and Separation Detection

Next, a method of transmitting generated multiplexed electron spin waves and a method of separating and detecting the multiplexed electron spin waves will be described.

The inventors have found that electron spin waves can be transported while maintaining waveforms thereof by appropriately using a drift electric field and an external magnetic field (S. Anghel, et al. “Spin-locked transport in a two-dimensional electron gas”, Physical Review B 101, 155414 (2020)).

Furthermore, it was found that by setting the strength of the spin-orbit interaction in a solid to a specific value, it was possible to stably retain only spin waves having a specific wavelength calculated therefrom, while eliminating other wavelength components.

FIGS. 2 to 4 show time evolutions when electron spin waves having different wavelengths are generated in solid-state devices having the same strength of spin-orbit interaction.

In FIG. 2, the electron spin waves have the same specific wavelength determined by the strength of the spin-orbit interaction, so the state of the electron spin waves is stable and shapes thereof can be maintained for a long time.

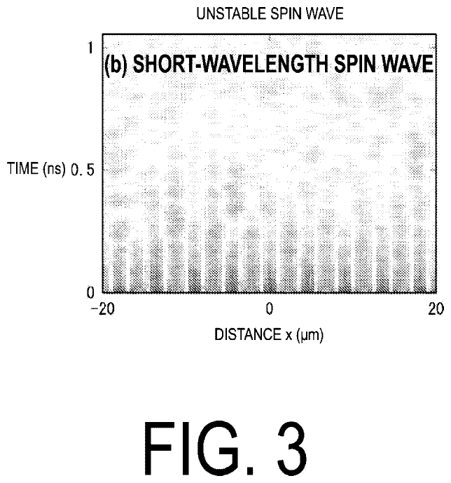

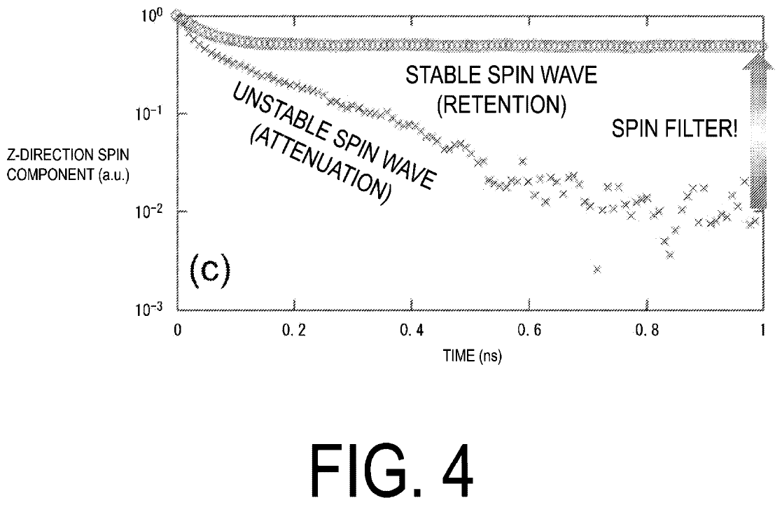

On the other hand, in FIG. 3, the electron spin waves have a wavelength different from the specific wavelength determined by the strength of the spin-orbit interaction of the semiconductor, so the electron spin waves lose shapes thereof in a short time. FIG. 4 shows the two in contrast, and it can be seen that the stable spin waves shown in FIG. 2 are different from the unstable spin waves shown in FIG. 3 in that it can maintain the electron spin waves in the Z direction for a predetermined time. This means that only the stable electron spin waves can be maintained and transmitted, while the unstable electron spin waves can be attenuated and eliminated.

The semiconductor assumed in FIGS. 2 to 4 is a semiconductor having the parameters defined in Table 3 above.

In FIG. 2, electron spin waves having a wavelength equal to a specific wavelength (λ₀=9.0 μm) that is uniquely determined by the strength of a spin-orbit interaction in the solid are excited at time 0, while in FIG. 3, electron spin waves having a different wavelength (λ=4.5 μm) are excited at time 0.

The shapes of the electron spin waves shown in FIG. 2 remain the same for a long time, but the shapes of the electron spin waves shown in FIG. 3 are destroyed due to a spin relaxation mechanism.

From the above, it can be said that when the strength of the spin-orbit interaction can be freely controlled, it is possible to select and extract only the information possessed by the electron spin waves with a desired wavelength.

This means that a spin filter has been achieved that can retain and transmit only stable electron spin waves (spin waves having a wavelength of λ₀=9.0 μm) and attenuate and eliminate unstable electron spin waves (spin wave having a wavelength of λ=4.5 μm).

In a semiconductor quantum well structure, the strengths of the Rashba spin-orbit interaction and the Dresselhaus spin-orbit interaction are uniquely determined by this structure, such as the quantum well width.

The wavelength of the electron spin wave is inversely proportional to the sum of the strengths of these two types of spin-orbit interactions. Therefore, once a quantum structure is determined, the wavelength of the electron spin wave that is specific to the material that constitutes that structure is uniquely determined. Here, in the semiconductor having the spin-orbit interaction with the strength shown in Table 3, the electron spin waves having a wavelength of λ₀=9.0 μm exist most stably.

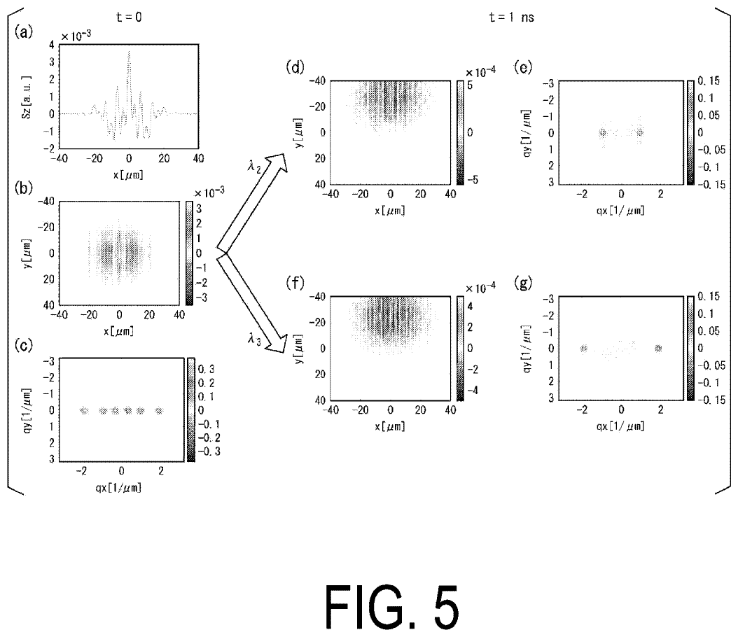

Using this principle, as an example, an example is shown in FIG. 5 that computationally demonstrates that by generating a state in which three electron spin waves are superposed and transporting the three superposed spin electron waves in this state using a drift electric field, it is possible to extract only stable spins.

The strength of the spin-orbit interaction is determined so that only an electron spin wave having a specific wavelength is stable, and three waves are generated, including the electron spin wave to be stable.

Specifically, FIG. 5 shows results of following the time evolutions of electron spin waves having three wavelength components of λ₁=20 μm, λ₂=6.7 μm, and λ₃=3.3 μm, while the electron spin waves are excited and transported in the +Y direction.

As described in the previous section, the wavelength (λ) of the electron spin wave has a property of being inversely proportional to the strength of the spin-orbit interaction. Therefore, by controlling the strength of the spin-orbit interaction in the material, for example by controlling the gate voltage, it is possible to select the wavelength of the electron spin wave that exists most stably.

Three electron spin waves, each having a wavelength component, were created in a Monte Carlo simulation by inputting the z component (Sz) of the electron spin spreading according to a Gaussian distribution at t=0 as a function of position into the following equation.

A specific function is represented by Sz(X)=cos(2π×0.05×X)+1.5 cos(2π×0.15×X)+0.7 cos(2π×0.3×X) (X: position [μm]).

In FIGS. 5(d) and (e), a semiconductor is assumed to have a spin-orbit interaction strength that stabilizes the wavelength of λ₂, and in FIGS. 5(f) and (g), a semiconductor is assumed to have a spin-orbit interaction strength that stabilizes the wavelength of λ₃.

FIGS. 5(b) and (c) show real space and reciprocal space distributions of multiplexed spin waves having three wavelength components of λ₁=20 μm, λ₂=6.7 μm, and λ₃=3.3 μm, and FIG. 5(a) shows a cross section at Y=0 in FIG. 5(b).

FIGS. 5(d) and (e) show the results when the multiplexed waves are injected into a region where λ₂ is stable and allowed to drift transport in the +Y direction for 1 ns, while FIGS. 5(f) and (g) show the results when the multiplexed waves are injected into a region where λ₃ is stable.

In these figures, it can be seen that the electron spin waves change shapes thereof while moving in the +Y direction as a whole. At this time, since the components other than the stably existing wavelength component disappeared over time, it was found that only the specific wavelength component was able to be extracted from the multiplexed waves of the electron spins.

This indicates that electron spin waves of different wavelengths can be superposed and transported, and in parallel only a specific wavelength component can be extracted. That is, it was found that by locally modulating the strength of the spin-orbit interaction at a specific location using an electron spin wave filter, the waveform of the electron spin wave passing through that location by the drift transport was able to be freely changed.

In the above description, it has been described that the strength of the spin-orbit interaction at a specific location is proportional to the gate voltage (V_{g}), for example, in the circuit in FIG. 8. Therefore, the strength of the spin-orbit interaction can be grasped from the value of V_{g}. Further, “locally modulated” means that only the region where the gate electrode is formed in the circuit in FIG. 8 is modulated, so that the region where the gate electrode is not formed is not modulated.

Furthermore, “passing by drift transport” means that by applying the gate voltage (Vₓ) in the circuit in FIG. 8, electrons can be moved from the left to the right of the circuit by an electric field. This is what is meant by drift transport, which is described as passing from a region where the gate electrode 5 is not formed, through a region where the gate electrode 5 is formed, and then entering a region where the gate electrode 5 is not formed on the opposite side.

From the above description, it has been proved that multiple electron spin waves can be superposed by controlling an amplitude, a phase, and a polarization degree of freedom of the electron spin waves by utilizing the persistent spin helix state in the crystal orientation dependence of the effective magnetic field due to the spin-orbit interaction generated in the semiconductor quantum well structure, and further that multiple electron spin waves can be transmitted in a solid-state device having the semiconductor quantum well structure.

Further, it has been proved that, in a solid-state device having the semiconductor quantum well structure (the above-described circuit), by transmitting electron spin waves having a wavelength equal to a specific wavelength determined uniquely from the strength of the spin-orbit interaction, and eliminating electron spin waves having a wavelength different from the specific wavelength determined uniquely from the strength of the spin-orbit interaction, only electron spin waves having a specific wavelength can be transmitted in a solid-state device.

Furthermore, it was found that when the number of electron spin waves was large, by subjecting the data obtained by real space measurement to fast Fourier transform to convert the data into wave number space data and then analyzing the data, the state in which the spin waves move and change shapes thereof was able to be easily confirmed. At this time, components other than the stably existing wavelength component disappeared over time, so it has been proved that only specific wavelength component can be extracted from the multiplexed waves.

From the above description, it was found that two or more types of electron spin waves were able to be superposed, the specific wavelengths of the respective electron spin waves were able to be maintained, and the superposed electron spin waves were able to be transmitted through the above-described transmission line without interfering with each other.

Therefore, using the above-mentioned multiplexed electron spin wave, transmission similar to wavelength division multiplexing in the optical field is possible, and when the transmitted multiplexed electron spin wave is separated into electron spin waves before multiplexing and information possessed by each electron spin wave is detected, it is considered that the conventional optical wavelength division multiplexing technique can be partially replaced by the multiplexed electron spin wave.

Hereinafter, an information transmission technique, an information recording technique, and an information separation analysis technique using multiplexed electron spin waves will be described in more detail.

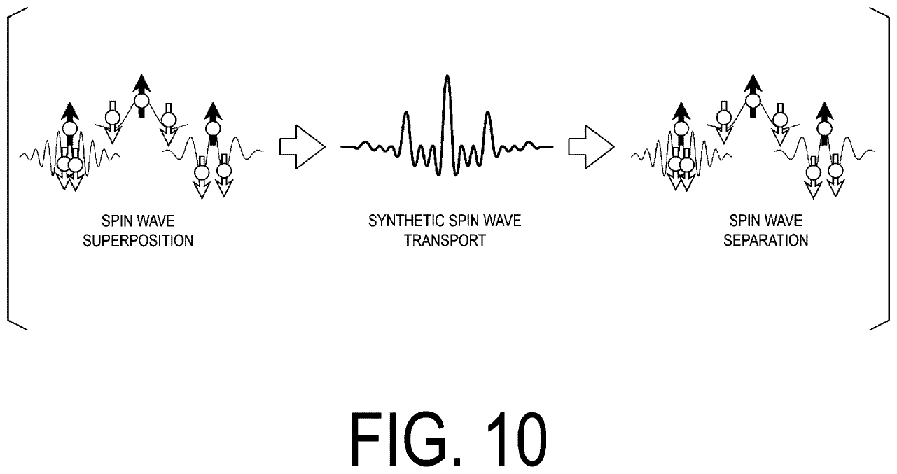

FIG. 10 is an explanatory diagram showing a concept of superposing electron spin waves to synthesize a multiplexed electron spin wave, transmitting the synthesized multiplexed electron spin wave, recording information contained in the multiplexed electron spin wave after transmission, and reading this information.

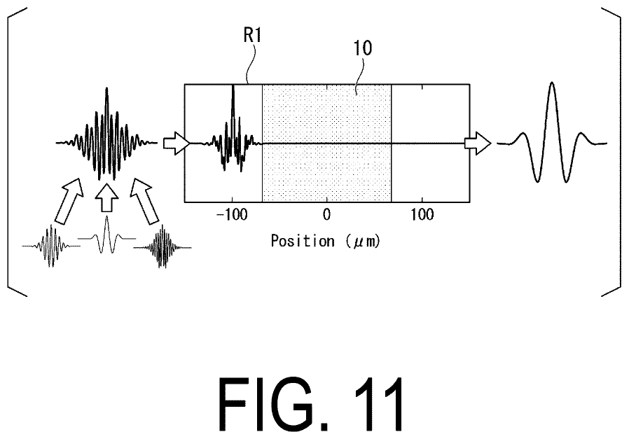

FIG. 11 is an explanatory diagram showing a concept of superposing electron spin waves to synthesize a multiplexed electron spin wave, transmitting the synthesized multiplexed electron spin wave along a transmission line R1 consisting of the aforementioned solid-state device, and modulating and drift transporting the multiplexed electron spin wave using a gate electrode 10 provided in the middle of the transmission line R1.

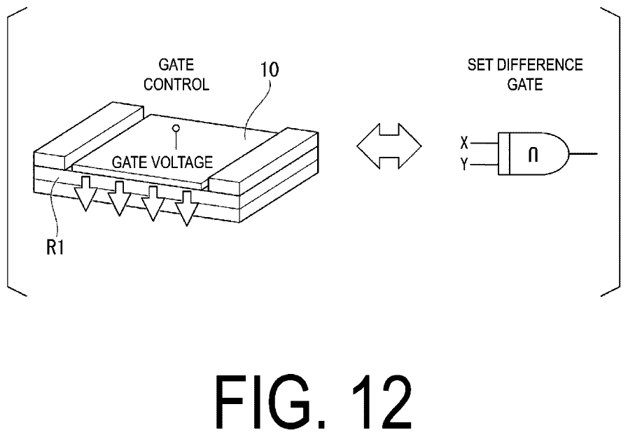

As described above, when gate control can be performed by using a gate structure shown in FIG. 12, as an example, in the middle of the transmission line R1, the gate structure can be used, for example, as an arithmetic element by a set difference gate shown in an equivalent circuit on the right side of FIG. 12. The gate structure shown in FIG. 12 is a structure in which the gate electrode 10 is layered on the transmission line R1 for the multiplexed electron spin waves, as shown, for example, in FIGS. 8 and 11.

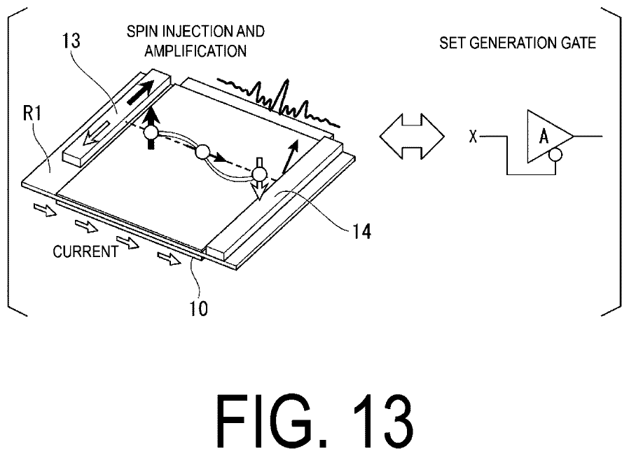

Further, when a solid-state device capable of spin injection and amplification shown in FIG. 13 can be achieved, the solid-state device can be used as an arithmetic element by a set generation gate shown in an equivalent circuit on the right side of FIG. 13.

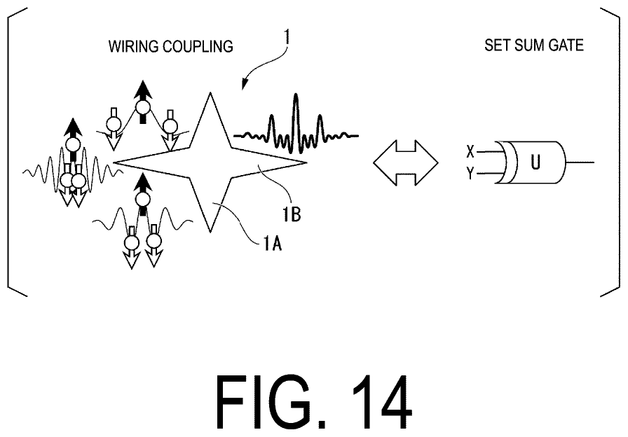

Furthermore, when a solid-state device in which wirings are coupled in a cross shape shown in FIG. 14 can be achieved, the solid-state device can be used as an arithmetic element by a set sum gate shown in an equivalent circuit on the right side of FIG. 14.

The solid-state device in which the wires are coupled in a cross shape as shown in FIG. 14 can adopt a structure equivalent to the wiring coupling unit 1 in which the wires 1A and 1B are coupled in a cross shape as shown in FIG. 8.

When these three types of arithmetic elements, such as the set difference gate, the set generation gate, and the set sum gate, that can be operated using basic logic are all available, it is possible to build a parallel arithmetic function capable of general-purpose parallel calculation. The structures of the solid-state devices shown in FIGS. 13 and 14 will be described in detail later.

A specific configuration for achieving optical communication-semiconductor multiplexed information transmission function using multiplexed electron spin waves will be further described below.

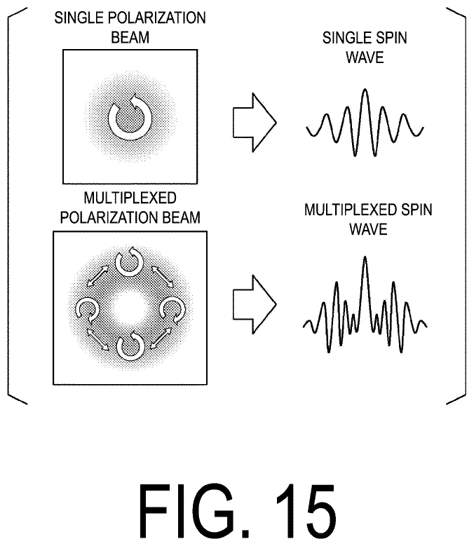

FIG. 15 shows a concept of a single polarization beam that is utilized in current optical communication technology. In optical information transmission in optical communication technology, information has been transmitted with a single polarization. However, in this embodiment, the multiplexed polarization is superposed on the optical signal. Individual pieces of optical polarization information can generate individual electron spin waves.

By using a multiplexed polarization beam based on this principle, multiplexed electron spin waves can be directly generated in a solid-state device made of a semiconductor. For example, based on the optical transition selection rule, the information multiplexed on the optical signal described above can be transferred to the electron spin wave. This enables photoelectric conversion of multiplexed information all together.

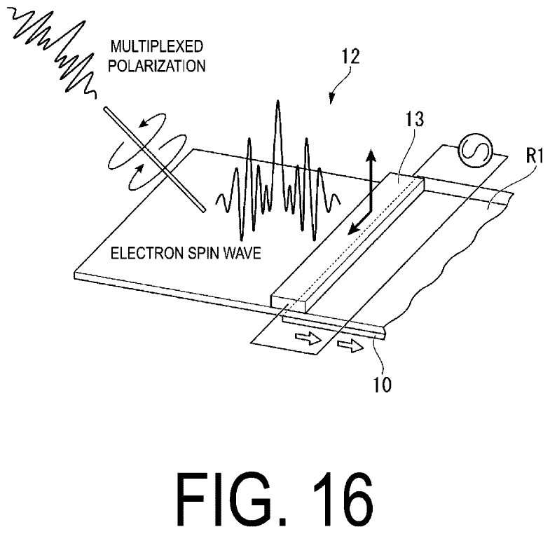

FIG. 16 shows an example of a configuration capable of achieving photoelectric conversion of multiplexed polarization beam information all together.

In FIG. 16, reference numeral 12 denotes a receiving unit provided with part of the transmission line R1 having the quantum well structure described above, and reference numeral 13 denotes a strip-shaped ferromagnetic layer, which is a ferromagnetic metal layer. A ferromagnetic layer 13 consists of a ferromagnetic metal layer, such as a Py (NiFe alloy) layer, a CoFeB layer, or a Heusler alloy layer. The ferromagnetic layer 13 is formed on a receiving unit 12 so as to extend from one end to the other end in the width direction of the receiving unit 12 and cross the receiving unit 12.

In the above-described configuration, the receiving unit 12 is irradiated with a multiplexed polarization beam, and a current is passed through the ferromagnetic layer 13, so that the electron spin wave can be controlled by spin pumping, which will be described later.

The structure for generating electron spin wave uses, for example, the semiconductor quantum structure shown in Table 1, and employs the principle of optical transition selection, which allows the angular momentum of light to be transferred to the angular momentum of spin by irradiating with the multiplexed polarization beam as shown in FIG. 15. By directly transferring the polarization information consisting of the angular momentum of light contained in the multiplexed polarization to the angular momentum of electron spins in the semiconductor quantum structure, that is, electron spin waves, the electron spin waves can be generated in the receiving unit 12 by the multiplexed polarization beam.

In information processing using the multiplexed electron spin waves according to the present embodiment, electron spin waves generated by spatial rotation of electron spins are utilized as wave nature information carriers in the solid-state device. A method of controlling multiplexed electron spin waves can be implemented as described below.

An effective magnetic field created by a spin-orbit interaction in a solid-state device can rotate electron spins in the time and space domains. In particular, electron spin waves can be stabilized under a special condition called a persistent spin helix state. This state can be controlled by voltage using a gate structure to the solid-state device from the outside as described above. By applying a gate voltage to the gate electrode, the wavelength of the electron spin wave that can be stabilized can be controlled as desired.

Therefore, when the multiplexed electron spin waves are drift transported to a region to which a gate voltage is applied, only the multiplexed electron spin waves that can be most stabilized by the applied gate voltage survive, and electron spin waves having other wavelengths can be eliminated. Using this principle, any electron spin wave can be electrically separated, as described above with reference to FIG. 8, and the concept of configuring a set difference gate by gate control through control of the gate voltage is shown in FIG. 12.

Next, a solid-state device capable of spin injection and amplification, as shown in FIG. 13, can be configured using a layered structure of ferromagnetic materials and a transmission line. In FIG. 13, as an example, by providing a strip-shaped first ferromagnetic layer 13 and a strip-shaped second ferromagnetic layer 14 in the middle of the transmission line R1, a solid-state device capable of spin injection and amplification can be configured.

By causing ferromagnetic resonance in a ferromagnetic material, precession can be induced in the magnetization of the ferromagnetic material. In a state in which precession occurs, when a current is applied from the ferromagnetic material to the transmission line R1 described above, electron spins that follow the magnetization direction are injected into the transmission line R1.

This makes it possible to inject electron spin waves that depend on the frequency of ferromagnetic resonance into the transmission line by the current. By temporally controlling the voltage applied between the layered structure of the ferromagnetic material and the transmission line, electron spin waves having a desired wavelength can be injected into the transmission line R1, making it possible to electrically generate multiplexed electron spin waves.

Also, by using the reverse principle of the above-described principle, electron spin waves can be detected using a ferromagnetic material. Specifically, magnetization dynamics or magnons having the same frequency as the electron spin waves are induced in the ferromagnetic material by magnetic resonance. When ferromagnetic resonance frequencies of the electron spin waves and the ferromagnetic material coincide, a spin angular momentum can be received from the electron spin waves, increasing the amplitude of the magnetization that resonates ferromagnetically.

On the other hand, when the frequency deviates from a resonance condition, nothing happens. By this principle, electron spin waves can be detected as changes in the line width and amplitude intensity of ferromagnetic resonance.

By using the various principles described above, the structures shown in FIGS. 12 to 14 can be used to achieve information processing using the wave nature information device. Specifically, three different gate operations shown in the equivalent circuits on the right side of FIGS. 12, 13, and 14 can be achieved, making it possible to configure a general-purpose parallel computer. This means that parallel arithmetic functions are constructed using electron spin waves.

Information recording using electron spin waves will be described in detail below.

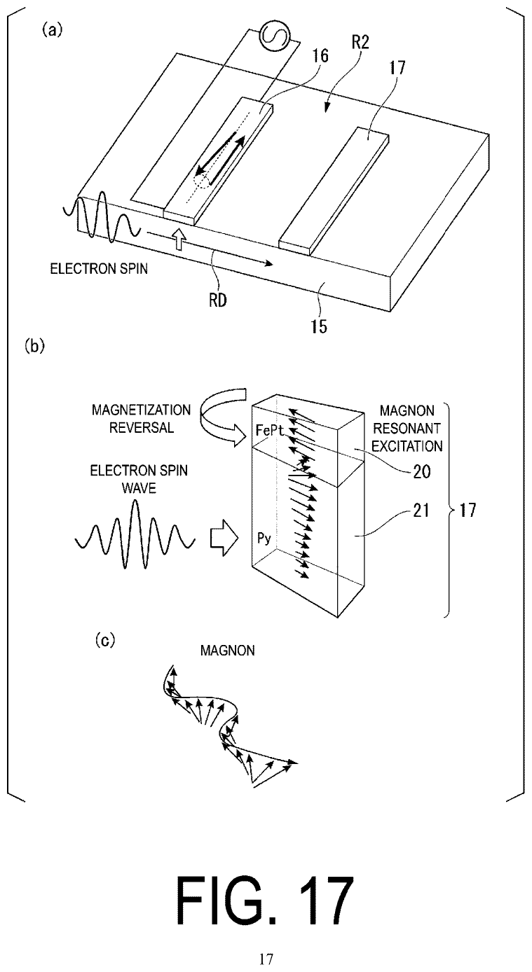

In information recording, a layered structure of ferromagnetic materials and a transmission line shown in FIG. 17 can be used.

In a transmission line R2 constituted of a nonmagnetic semiconductor 15 in FIG. 17(a), a strip-shaped first ferromagnetic layer 16 and a strip-shaped second ferromagnetic layer 17 are formed with a predetermined space on the transmission line R2 along the transport direction of the electron spin waves. The nonmagnetic semiconductor 15 is a semiconductor as a solid-state device having a III-V compound semiconductor quantum well structure on a substrate, and functions as the transmission line R2 that carries electron spin waves as in the example described above.

The length directions of the first ferromagnetic layer 16 and the second ferromagnetic layer 17 are oriented perpendicular to a transport direction RD of the electron spin waves.

As shown in FIG. 17(b), the ferromagnetic layer 17 has a structure in which an upper magnetic layer (recording magnetic layer) 20 and a lower magnetic layer (base magnetic layer) 21 are layered, where the upper magnetic layer 20 is a layer that records information and the lower magnetic layer 21 is a layer that excites a magnon, which will be described later. The upper magnetic layer 20 consists of, for example, an FePt layer, and the lower magnetic layer 21 consists of, for example, a ferromagnetic metal layer such as a Py (NiFe alloy) layer, a CoFeB layer, or a Heusler alloy layer.

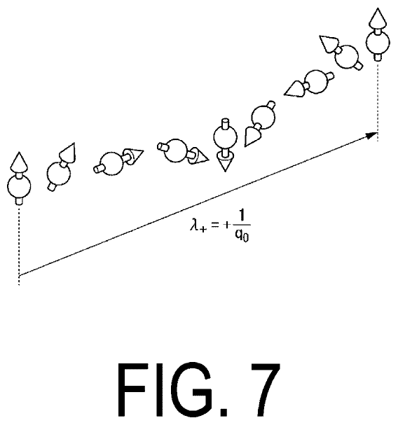

By transferring the spin angular momentum of the electron spin from the multiplexed electron spin wave propagating through the nonmagnetic semiconductor 15 to the ferromagnetic material of the first ferromagnetic layer 16, a magnon can be excited in the ferromagnetic material. A magnon is a wave having a continuous change in magnetic order, as shown in FIG. 17(c), and the magnetization is fixed. On the other hand, the electron spin wave is a wave in which the electron spin rotates around the effective magnetic field, as described above with reference to FIG. 7.

The upper magnetic layer 20 is magnetically coupled to the lower magnetic layer 21, and when magnons and spin waves are excited in the lower magnetic layer 21 due to resonant excitation of magnons by electron spin waves, the magnetization of the upper magnetic layer 20 is also reversed accordingly.

Since magnons can be excited only when the magnons have the same resonance frequency as the electron spin waves, it means that information can be selectively written in the upper magnetic layer 20 depending on the wavelength of the electron spin wave. Specifically, as an example, the magnetization state is shown by multiple arrows in FIG. 17(b).

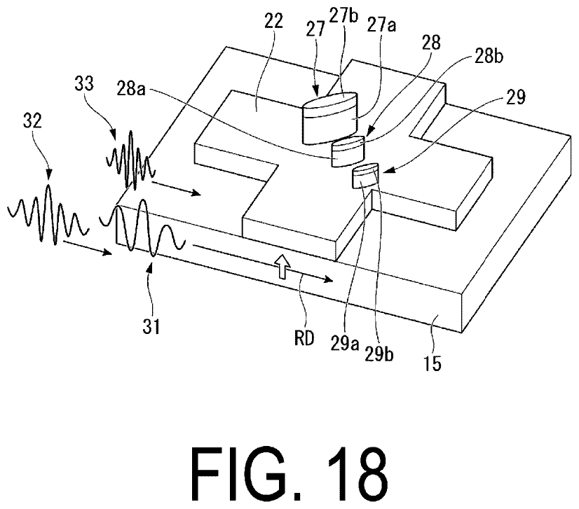

Taking the above-described state into consideration, more specifically, a structure can be adopted in which three ferromagnetic materials, a first recording magnetic material 27, a second recording magnetic material 28, and a third recording magnetic material 29, are formed on a semiconductor solid-state device 22 having a cross shape in plan view, as shown in FIG. 18. As an example, the semiconductor solid-state device 22 is based on the layered structure shown in Table 1 above, and has a structure equivalent to the wiring coupling unit 1 shown in FIG. 8.

The first recording magnetic material 27 is a layer formed by layering an upper magnetic layer (recording magnetic layer) 27b for recording information and a lower magnetic layer (base magnetic layer) 27a having a magnon resonance frequency.

The second recording magnetic material 28 is a layer formed by layering an upper magnetic layer (recording magnetic layer) 28b for recording information and a lower magnetic layer (base magnetic layer) 28a having a magnon resonance frequency, and the third recording magnetic material 29 is a layer formed by layering an upper magnetic layer (recording magnetic layer) 29b for recording information and a lower magnetic layer (base magnetic layer) 29a having a magnon resonance frequency.

In the structure in FIG. 18, when a multiplexed electron spin wave having different electron spin wave wavelengths (i.e., frequencies) reach the first recording magnetic material 27, the second recording magnetic material 28, and the third recording magnetic material 29, the ferromagnetic materials that can resonate differ depending on the wavelength=frequency of the electron spin wave.

For example, a first electron spin wave indicated by reference numeral 31 in FIG. 18 can excite a magnon only in the lower magnetic layer 27a of the first recording magnetic material 27, causing the upper magnetic layer 27b to reverse the magnetization and change the magnetization state.

A second electron spin wave indicated by reference numeral 32 in FIG. 18 can excite a magnon only in the lower magnetic layer 28a of the second recording magnetic material 28, causing the upper magnetic layer 28b to reverse the magnetization and change the magnetization state.

A third electron spin wave indicated by reference numeral 33 in FIG. 18 can excite a magnon only in the lower magnetic layer 29a of the third recording magnetic material 29, causing the upper magnetic layer 29b to reverse the magnetization and change the magnetization state.

Thus, by selectively exciting only the magnons of the ferromagnetic materials having the same resonance frequencies as the three types of electron spin waves, the information contained in the multiplexed electron spin wave can be recorded in the first recording magnetic material 27, the second recording magnetic material 28, and the third recording magnetic material 29 as multi-states in a nonvolatile manner. Using this principle, information contained in the multiplexed electron spin wave can be electrically detected.

In each of the recording magnetic materials 27, 28, and 29, information can be recorded on the upper magnetic layer side by the magnon excited on the lower magnetic layer side, according to the same principle as in the example described in FIGS. 17(a) and (b).

In the description based on FIGS. 17 and 18, only the configuration having the magnetic layer in which the magnetization is oriented in the film surface has been described, but a combination structure of a perpendicular magnetization film in which the magnetization is oriented perpendicular to the film surface and a magnetic vortex can also be used to record and read information described above.

As the perpendicular magnetization film, for example, a film such as (Fe—Pt alloy, Fe—Pd alloy, Mn-based alloy, Co/Pt multilayer film, Co/Pd multilayer film, Co/Ni multilayer film) can be used, and as the magnetic vortex, for example, a configuration such as (Co—Fe alloy, Ni—Fe alloy, Co—Mn—Si alloy, Co—Fe—Al alloy, Co—Fe—Si alloy) can be used.

In the configuration previously described based on FIGS. 17 and 18, it was described that the magnon was excited in the lower magnetic layer and the state of magnetization was recorded in the upper magnetic layer, but when the configuration shown in FIGS. 17 and 18 is vertically inverted, a magnon may be resonantly excited in the upper magnetic layer and the state of magnetization may be recorded in the lower magnetic layer. In this case, the upper magnetic layer is used as a base magnetic layer and the lower magnetic layer is used as a recording magnetic layer.

For example, when the transmission line R2 is placed on a lower surface side of the nonmagnetic semiconductor 15, the upper magnetic layer is formed so as to be in contact with a lower surface of the nonmagnetic semiconductor 15, and the lower magnetic layer is formed below the upper magnetic layer. In this case, the electron spin wave in the transmission line R2 excites a magnon on the upper magnetic layer side and records the state of magnetization on the lower magnetic layer side. In the configuration of the present embodiment, a base magnetic layer capable of exciting magnon resonance is placed on the side in contact with the transmission line R2, and a recording magnetic layer capable of reversing magnetization is provided so as to be connected to the base magnetic layer.

The configurations shown in FIGS. 17 and 18 are examples of the arrangement of the magnetic layers, and the magnetic layers may be vertically inverted as described above, and the arrangement direction and the like of the nonmagnetic semiconductor 15 and the transmission line R2 are not particularly limited.

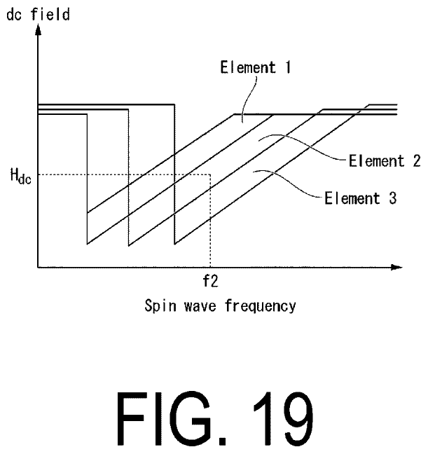

FIG. 19 is a graph showing conditions of magnetic fields and frequencies for causing magnetization reversal in the first recording magnetic material (Element 1) 27, the second recording magnetic material (Element 2) 28, and the third recording magnetic material (Element 3) 29, where the horizontal axis represents the frequency of electron spin wave and the vertical axis represents the magnetic field.

As an example, the first recording magnetic material (Element 1) 27 is a recording magnetic material having a long elliptical shape in plan view with a long diameter of about 1 μm and a short diameter of about 500 nm, the second recording magnetic material (Element 2) 28 is a recording magnetic material having a long elliptical shape in plan view with a long diameter of about 500 nm and a short diameter of about 250 nm, and the third recording magnetic material (Element 3) 29 is a recording magnetic material having a long elliptical shape in plan view with a long diameter of about 250 nm and a short diameter of about 125 nm.

From a relationship shown in FIG. 19, assuming that the magnetic characteristics (spin wave frequency) of individual magnetic layers are known, it is possible to determine which recording magnetic material has recorded information from a value of a DC component Hdc of the magnetic field.

The above-described nonvolatile multi-state recording method will be described in detail below.

Table 4 below shows combinations to illustrate the multi-state nonvolatile recording method.

TABLE 4

| FM1 | FM2 | FM3 | V (FM1) | V (FM2) | V (FM3) | Output |
|---|---|---|---|---|---|---|
| 0 | 0 | 0 | −4 | −2 | −1 | −7 |
| 1 | 0 | 0 | 4 | −2 | −1 | 1 |
| 1 | 1 | 0 | 4 | 2 | −1 | 5 |
| 1 | 0 | 1 | 4 | −2 | 1 | 3 |
| 1 | 1 | 1 | 4 | 2 | 1 | 7 |
| 0 | 1 | 1 | −4 | 2 | 1 | −1 |
| 0 | 0 | 1 | −4 | −2 | 1 | −5 |
| 0 | 1 | 0 | −4 | −2 | −1 | −3 |

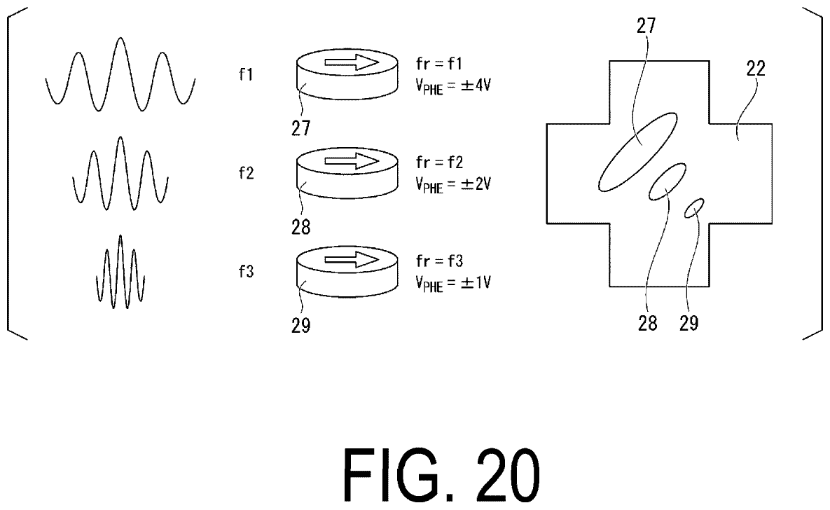

As shown in Table 4 and FIG. 20, ferromagnetic materials having different resonance frequencies f1, f2, and f3 corresponding to the wavelengths of the electron spin waves are prepared. For example, these refer to the ferromagnetic materials of the first recording magnetic material 27, the second recording magnetic material 28, and the third recording magnetic material 29 shown in FIG. 18. Only when the frequency of the electron spin is equal to the ferromagnetic resonance frequency of the magnetization, a magnon is excited as in the case shown in FIG. 17(b), causing magnetization reversal in the upper magnetic layer of each recording magnetic material.

In the example shown in Table 4 and FIG. 20, for example, the first recording magnetic material 27 can be set to have a resonance frequency fr=f1 and V_{PHE}=±4 V, the second recording magnetic material 28 to have a resonance frequency fr=f2 and V_{PHE}=±2 V, and the third recording magnetic material 29 to have a resonance frequency fr=f3 and V_{PHE}=±1 V. Here, the output V_{PHE} can be controlled by the size of the element. This takes advantage of the fact that the larger the element, the greater the resistance change due to the planar Hall effect.

When three types of electron spin waves are multiplexed, multiplexed states can be achieved in three powers of two, that is, eight different types. In order to record these eight types of information, a structure in which recording magnetic materials are arranged in three rows is fabricated. Depending on the types and presence/absence of the electron spin waves, eight different states can be recorded, as shown in Table 4.

Thus, multiplexed information of the multiplexed electron spin wave can be recorded as multi-state nonvolatile magnetic recording.

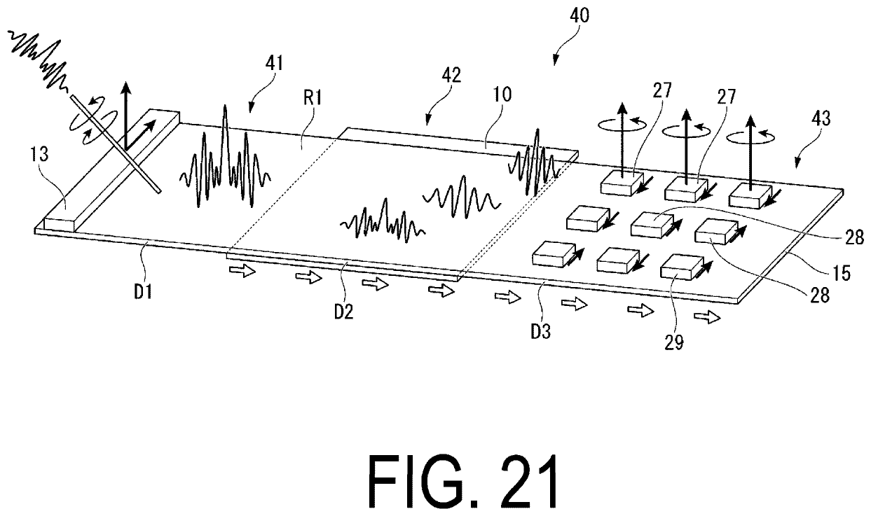

FIG. 21 is a configuration diagram showing an example of a wave nature information device (electron spin wave multiplexing device) configured using a structure capable of information processing, information transmission, and information recording using the electron spin waves described above.

A wave nature information device (electron spin wave multiplexing device) 40 of this example includes a receiving unit 41, a modulation unit 42, and a recording unit 43. In addition, the transmission lines R1 described previously in detail above are formed in the receiving unit 41, the modulation unit 42, and the recording unit 43 so as to connect the receiving unit 41, the modulation unit 42, and the recording unit 43.

The receiving unit (multiplex photoelectric conversion unit) 41 has a structure equivalent to the structure shown in FIG. 16, and has a function of directly generating a multiplexed electron spin wave in a semiconductor by multiplex photoelectric conversion using multiplexed polarization.

When the modulation unit 42 adopts the structure having the gate electrode 10 described above with reference to FIGS. 11 and 12, the modulation unit 42 has a function as a set difference gate for gate-controlling the multiplexed electron spin wave transmitted through the semiconductor solid-state device.

When the modulation unit 42 adopts the structure shown in FIG. 13, the modulation unit 42 has a function as a set generation gate capable of spin injection and amplification.

When the modulation unit 42 adopts the structure shown in FIG. 14, the modulation unit 42 has a function as a set sum gate.

One or more of the configurations shown in FIGS. 11 to 14 can be formed in the transmission line R1 for the multiplexed electron spin waves. The transmission lines R1 formed in the receiving unit 41, the modulation unit 42, and the recording unit 43 are all transmission lines formed as solid-state devices in each of which the above-described semiconductor quantum well structure shown in Table 1 or the like is formed on a substrate.

In the wave nature information device (electron spin wave multiplexing device) 40, for convenience, the transmission line R1 formed in the receiving unit 41 can be referred to as a transmission line formed in a first solid-state device D1. Similarly, the transmission line R1 formed in the modulation unit 42 can be referred to as a transmission line formed in a second solid-state device D2, and the transmission line R1 formed in the recording unit 43 can be referred to as a transmission line formed in a third solid-state device D3.

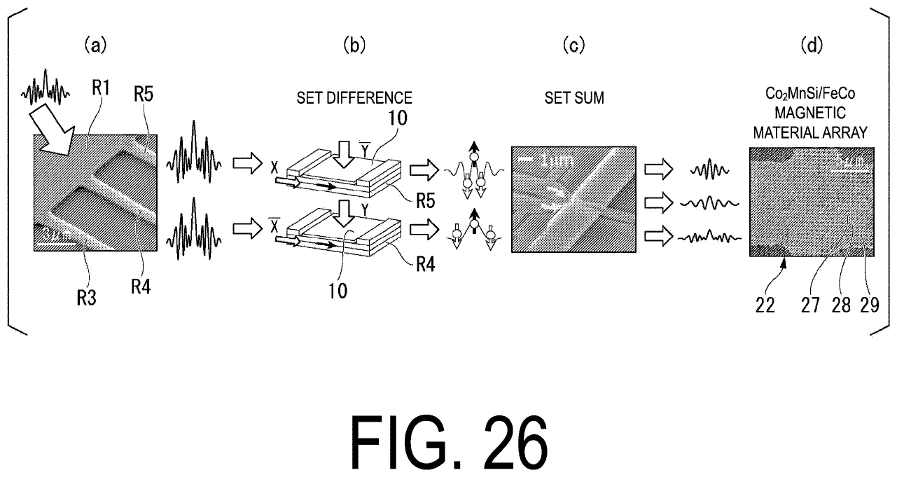

In the wave nature information device 40 shown in FIG. 21, multiple first recording magnetic materials 27, multiple second recording magnetic materials 28, and multiple third recording magnetic materials 29 are arrayed vertically and horizontally in a plane direction on the solid-state device D3 of the recording unit 43. When the multiple first recording magnetic materials 27, the multiple second recording magnetic materials 28, and the multiple third recording magnetic materials 29 are arrayed in the recording unit 43, a total of about several tens to several hundreds of first recording magnetic materials 27, second recording magnetic materials 28, and third recording magnetic materials 29 can be provided as shown in an example to be described later based on FIG. 26(d).

As described previously, when the first recording magnetic materials 27, the second recording magnetic materials 28, and the third recording magnetic materials 29 are provided, recording of 2³=8 states can be achieved. By providing several tens to several hundreds of the first recording magnetic materials 27, the second recording magnetic materials 28, and the third recording magnetic materials 29 in the recording unit 43 as described above, information can be recorded.

With the wave nature information device 40 shown in FIG. 21, information multiplexed by polarization in optical communication is collectively converted into a multiplexed electron spin wave by the receiving unit 41. Subsequently, the multiplexed electron spin wave is transmitted through the transmission line R1, which is the solid-state device having a semiconductor quantum well structure such as InGaAs/InAlAs, and the spin-orbit interaction of the multiplexed electron spin wave is controlled by the gate electrode 10 provided in the modulation unit 42, thereby achieving information processing as a set difference gate using the multiplexed electron spin wave.

Finally, regarding the information contained in the processed multiplexed electron spin wave, the multiplexed information contained in the multiplexed electron spin wave can be recorded in a nonvolatile manner as multi-states as described above using the recording unit 43 in which multiple ferromagnetic materials are arrayed. This makes it possible to construct a system capable of operating multiplexed information using the wave nature information device 40 in all of information communication, information processing, and information recording.

Next, the principle of spin injection, transport of an electron spin wave, and detection of the electron spin wave using the above-described layered structure of ferromagnetic metals and a transmission line will be described.

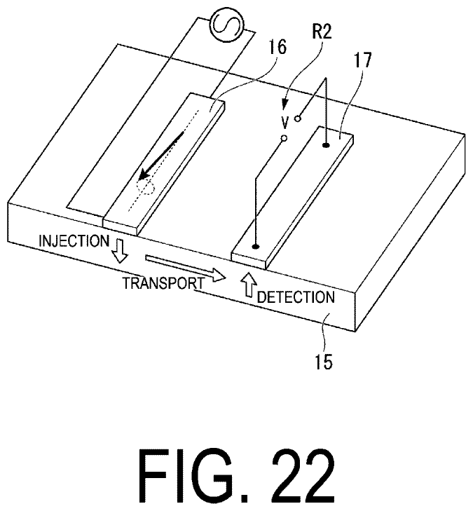

FIG. 22 shows an example in which the first ferromagnetic layer 16 and the second ferromagnetic layer 17 consisting of thin films each having a long and narrow rectangular shape in plan view are formed on the upper surface of the nonmagnetic semiconductor 15 shown in FIG. 17(a).

By subjecting a ferromagnetic material to ferromagnetic resonance, the magnetization can be made to process over time. The magnetization direction changes over time due to the precession of magnetization. For example, upward and downward magnetization components perpendicular to the surface of a ferromagnetic thin film are generated. These magnetization components rotate over time. When a bias current is applied to this rotational motion to cause electrons to flow from the first ferromagnetic layer 16 to the nonmagnetic semiconductor 15, the electrons can be injected while changing the upward spin and the downward spin over time, forming an electron spin wave. This is the electrical injection of the electron spin wave.

As described in the previous example, the electron spin wave is drift transported by the bias voltage applied from the gate electrode, and when the recording magnetic material for detection has the same ferromagnetic resonance frequency as the wavelength of the electron spin wave, that is, the precession frequency, the spin angular momentum can be transferred to the ferromagnetic material by mutual conversion of spin angular momentum (i.e., by spin transfer torque), and the line width and the amplitude of the ferromagnetic resonance change.

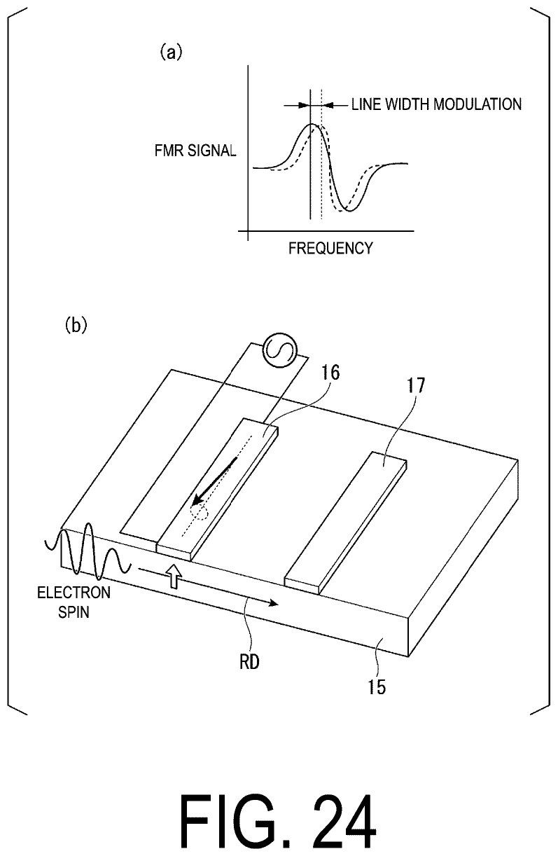

This can be detected by electrically, in the second ferromagnetic layer 17, enabling electrical detection of the electron spin wave. FIG. 24 shows a change in the line width of the ferromagnetic resonance. As the line width can be modulated as shown in FIG. 24, it is understood that the spin angular momentum can be transferred from the electron spin wave to the second ferromagnetic layer 17 and the magnetization dynamics can be modulated.

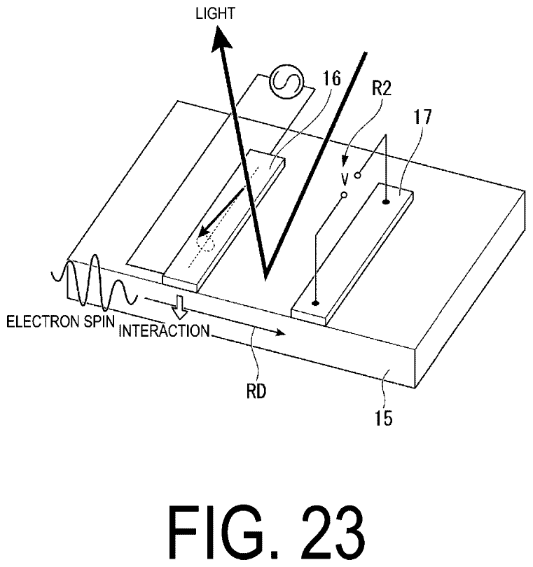

FIG. 23 is a configuration diagram for describing the principle that the electron spin wave can be controlled by spin pumping in the configuration shown in FIG. 17(a) in which the first ferromagnetic layer 16 and the second ferromagnetic layer 17 are provided on the upper surface of the nonmagnetic semiconductor 15.

As shown in FIG. 23, when the electron spin wave is transported along the transmission line R2, the upper surface of the nonmagnetic semiconductor 15 is irradiated with light. This configuration allows the modulation of the electron spin wave to be detected by an optical method in parallel with an electrical method.

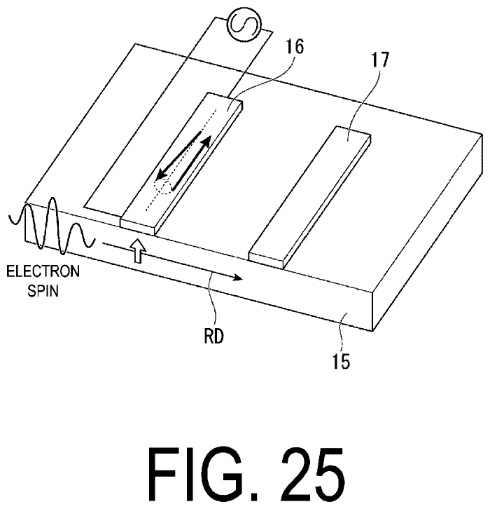

FIG. 25 shows an example of a case where the spin angular momentum transferred from the electron spin wave is increased and the magnetization is reversed in the configuration in which the first ferromagnetic layer 16 and the second ferromagnetic layer 17 are provided on the upper surface of the nonmagnetic semiconductor 15 shown in FIG. 17(a). Since the condition for the ferromagnetic resonance to occur is only for a ferromagnetic material having the same frequency as the electron spin wave, it is understood that information contained in the electron spin wave can be selectively recorded only in a specific ferromagnetic material.

FIG. 26 shows a modification of the wave nature information device 40 shown in FIG. 21.

In the wave nature information device 40 shown in FIG. 21, the transmission line R1, which is a solid-state device, formed in the receiving unit 41 can be divided into three thin transmission lines R3, R4, and R5 as shown in FIG. 26(a), so that multiplexed electron spin waves can be transmitted along any of the three transmission lines R3, R4, and R5.

Then, by providing the gate electrode 10 for each transmission line to perform gate control as shown in FIG. 26(b), the transmission lines R4 and R5 can each function as a set difference gate. Further, by combining the branched transmission lines R4 and R5 at terminal sides of the transmission lines R4 and R5 as shown in FIG. 26(c), and integrating into a single transmission line, a set sum gate can be configured.

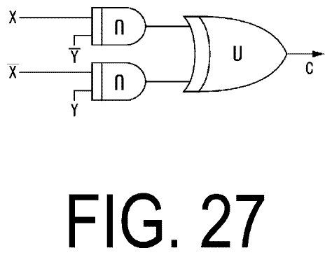

A structure in which two set difference gates are connected to one set sum gate as shown in FIGS. 26(b) and 26(c) can be represented by an equivalent circuit shown in FIG. 27.

At the terminal side of the transmission line integrated after branching as described above, the semiconductor solid-state device 22 having a cross shape in plan view, which is the structure previously described with reference to FIG. 18, is formed as shown in FIG. 26(d). Further, on the semiconductor solid-state device 22, several hundreds of recording magnetic materials are formed vertically and horizontally in the plane direction of the upper surface of the solid-state device 22.

FIG. 26(d) shows a state in which a large number of recording magnetic materials having a layered structure of a Co₂MnSi layer and a FeCo layer, which have structures equivalent to the first recording magnetic material 27, the second recording magnetic material 28, and the third recording magnetic material 29 described above based on FIG. 18. The example in FIG. 26(d) shows a state in which about 400 recording magnetic materials are formed in a region of about 15 μm×15 μm in the semiconductor solid-state device 22 having a cross shape in plan view.

The structures shown in FIGS. 26(a), (c), and (d) can all be manufactured using the current semiconductor microfabrication technology, so the structures shown in FIGS. 21 and 26 can be achieved on a substrate as solid-state devices.

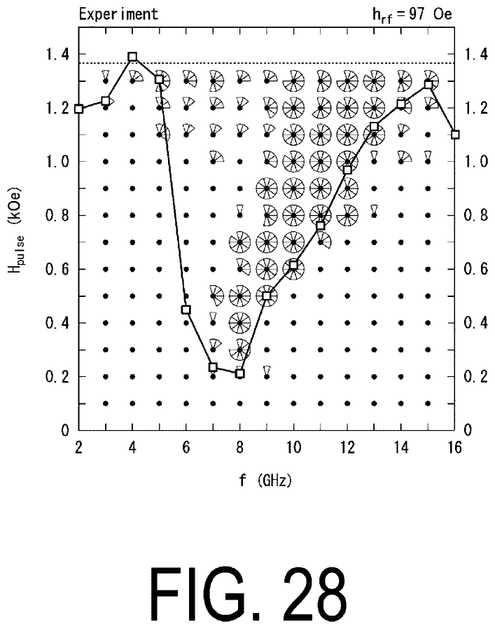

FIG. 28 is an explanatory diagram that assumes a case in which, in a structure in which multiple recording magnetic materials are arrayed vertically and horizontally, when the magnetization of each recording magnetic material is reversed due to a spin transfer effect from an electron spin wave, resonant switching by spin pumping is possible.

As shown in FIG. 28, selective writing is considered to be possible by adjusting the resonance frequency of the recording magnetic material to be written to.

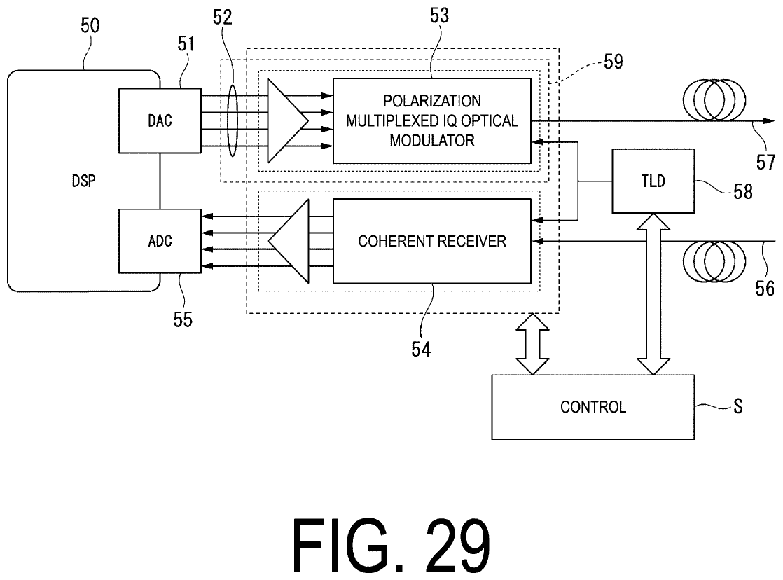

FIG. 29 is a configuration diagram showing an example of an optical high-speed transmission system for next-generation optical communications.

In FIG. 29, reference numeral 50 denotes a digital signal processing circuit, 51 denotes a digital-to-analog converter (DAC), 52 denotes an analog multiplexer, 53 denotes a polarization multiplexed in-phase quadrature (IQ) optical modulator, 54 denotes a coherent receiver, and 55 denotes an analog-to-digital converter (ADC).

An optical signal (laser) as an analog signal is input from an input transmission fiber 56 to the coherent receiver 54, and the signal converted to a digital signal by the analog-to-digital converter 55 is processed by the digital signal processing circuit 50.

The digital signal processed by the digital signal processing circuit 50 is converted to an analog signal by the digital-to-analog converter 51, and an optical modulation signal is generated by the polarization multiplexed IQ optical modulator 53 and transmitted through an output transmission fiber 57.

The polarization multiplexed IQ optical modulator 53 and the analog multiplexer 52 constitute, as an example, an integrated module 59.

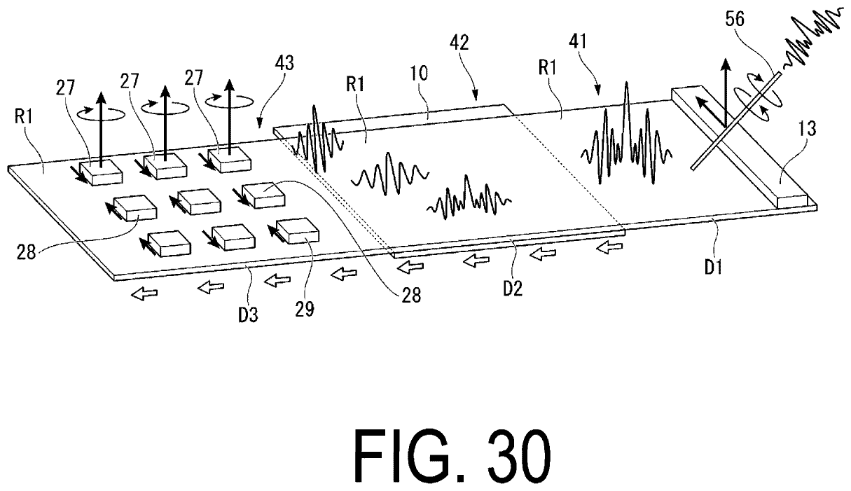

It is also desirable to integrate the structures from the coherent receiver 54 to the analog-to-digital converter 55 to an integrated module, and the wave nature information device (electron spin wave multiplexing device) 40 shown in FIG. 21 can be applied to the above-mentioned structure as the configuration shown in FIG. 30.

The receiving unit 41 receives the multiplexed polarization from the input transmission fiber 56 to generate multiplexed electron spin waves, and the multiplexed electron spin waves can be transmitted along the transmission line R1 without wavelength separation.

Further, the information contained in the multiplexed electron spin waves can be recorded in the first to third recording magnetic materials 27, 28, and 29 of the recording unit 43. The pieces of information recorded in the first to third recording magnetic materials 27, 28, and 29 are read out as the digital signals shown in Table 4 above, thereby performing analog-to-digital conversion. By sending this digital signal to the digital signal processing circuit 50, the structure from the coherent receiver 54 to the analog-to-digital converter 55 shown in FIG. 29 can be replaced.

All of the structures of the wave nature information device (multiplexed electron spin wave transmission device) 40 shown in FIGS. 21 and 30 can be formed in a range of about 10 μm² using the current general semiconductor miniaturization technology, so the above-described optical transmission system can be achieved in a smaller size.

### REFERENCE SIGNS LIST

1 Wiring coupling unit, 1A, 1B Wiring, 2, 3 Power source, 2a, 3a Wiring, 5 Gate electrode layer, 6 Power source, V_{g} Gate voltage, Vₓ Voltage applied in x direction, V_{y} Voltage applied in y direction, 10 Gate electrode, 13, 14 Ferromagnetic layer, 15 Nonmagnetic semiconductor, 16 First ferromagnetic layer, 17 Second ferromagnetic layer, 20 Upper magnetic layer (recording magnetic layer), 21 Lower magnetic layer (base magnetic layer), 27 First recording magnetic material, 27a Lower magnetic layer (base magnetic layer), 27b Upper magnetic layer (recording magnetic layer), 28 Second recording magnetic material, 28a Lower magnetic layer (base magnetic layer), 28b Upper magnetic layer (recording magnetic layer), 29 Third recording magnetic material, 29a Lower magnetic layer (base magnetic layer), 29b Upper magnetic layer, 40 Multiplexing device (wave nature information device), 41 Receiving unit, 42 Modulation unit, 43 Recording unit, D1 First solid-state device, D2 Second solid-state device, D3 Third solid-state device.

I claim:

1. An electron spin wave multiplexing device comprising:
a receiving unit that includes a first solid-state device having a semiconductor quantum well structure, and receives a multiplexed electron spin wave by synthesizing multiple electron spin waves;
a modulation unit that includes a second solid-state device having a semiconductor quantum well structure and connected to the receiving unit, and modulates the multiplexed electron spin wave from the receiving unit; and
a recording unit that includes a third solid-state device having a semiconductor quantum well structure and connected to the modulation unit, receives the multiplexed electron spin wave passed through the modulation unit, and includes multiple recording magnetic materials that record information contained in the multiplexed electron spin wave in a nonvolatile manner, wherein
the modulation unit is a modulation unit that has a function of controlling at least one of an amplitude, a phase, and a polarization degree of freedom of the multiple electron spin waves by utilizing a persistent spin helix state in crystal orientation dependence of an effective magnetic field due to a spin-orbit interaction generated in a semiconductor quantum well structure.

2. The electron spin wave multiplexing device according to claim 1, the electron spin wave multiplexing device, by transmitting an electron spin wave having a wavelength equal to a specific wavelength determined uniquely from spin-orbit interaction strength and eliminating an electron spin wave having a wavelength different from the specific wavelength determined uniquely from the spin-orbit interaction strength in the solid-state device having the semiconductor quantum well structure, having a function of transmitting only an electron spin wave having a specific wavelength in the solid-state device.

3. The electron spin wave multiplexing device according to claim 1, the electron spin wave multiplexing device, when the number of the multiple electron spin waves is large, having a function of converting data obtained by real space measurement into data in wave number space by fast Fourier transform and analyzing the data.

4. The electron spin wave multiplexing device according to claim 1, wherein the modulation unit is provided with one or more of a gate electrode for voltage application, a ferromagnetic layer for spin injection and amplification, and a wiring coupling unit that couples the multiple electron spin waves.

5. The electron spin wave multiplexing device according to claim 1, wherein the multiple recording magnetic materials each having a base magnetic layer and a recording magnetic layer are arrayed in the recording unit, the base magnetic layer is a magnetization reversal layer that excites a magnon using each of the multiple electron spin waves and is capable of magnetization reversal by resonating with excitation of the magnon, the recording magnetic layer has a function of magnetization reversal corresponding to the magnetization reversal of the base magnetic layer and nonvolatile recording of the information contained in the multiplexed electron spin wave with this magnetization reversal, and the information contained in the multiplexed electron spin wave is recorded as multi-states by the multiple recording magnetic materials arrayed.

6. The electron spin wave multiplexing device according to claim 1, wherein a set difference gate is configured by providing a gate electrode for voltage application to the modulation unit.

7. The electron spin wave multiplexing device according to claim 1, wherein a set generation gate is configured by providing a ferromagnetic layer for spin injection and amplification to the modulation unit.

8. The electron spin wave multiplexing device according to claim 1, wherein a set sum gate is configured by providing a wiring coupling unit that couples the multiple electron spin waves to the modulation unit.

9. The electron spin wave multiplexing device according to claim 1, wherein the receiving unit has a function of generating the multiplexed electron spin wave by irradiation with a laser on which information contained in a multiplexed polarization beam for optical communication is recorded, and has a multiplexed information transmission function by writing information corresponding to the multiplexed polarization beam for optical communication in the multiplexed electron spin wave.

10. The electron spin wave multiplexing device according to claim 1, wherein a parallel computer is constructed by including a set difference gate is configured by providing a gate electrode for voltage application to the modulation unit, a set generation gate is configured by providing a ferromagnetic layer for spin injection and amplification to the modulation unit, and a set sum gate is configured by providing a wiring coupling unit that couples the multiple electron spin waves to the modulation unit.

11. The electron spin wave multiplexing device according to claim 5, wherein the multiple recording magnetic materials are provided vertically and horizontally in a plane direction of the recording unit, and each of the multiple recording magnetic materials has a function as resonant switching by spin pumping due to a spin transfer effect from the multiplexed electron spin wave.

12. The electron spin wave multiplexing device according to claim 11, the electron spin wave multiplexing device employing a structure that exhibits angle dependence due to a planar Hall effect for each of the multiple recording magnetic materials, and having a function of reading information in the recording unit by reading in-plane magnetization in a region where the multiple recording magnetic materials are formed.

13. The electron spin wave multiplexing device according to claim 11, the electron spin wave multiplexing device
employing a structure that exhibits an anomalous Hall effect in each of the multiple recording magnetic materials, and
having a function of reading information in the recording unit by reading a perpendicular magnetization component in a region where the multiple recording magnetic materials are formed when each of the multiple recording magnetic materials is magnetically oriented perpendicular to a film surface.
